(19) United States
(12) Patent Application Publication
(10) Pub. No.: US 2026/0107452 A1
(43) Pub. Date: Apr. 16, 2026

(54) SEMICONDUCTOR DEVICE INCLUDING CAPACITOR

(71) Applicant: SAMSUNG ELECTRONICS CO., LTD., Suwon-si (KR)

(72) Inventors: Seungjun SHIN, Suwon-si (KR); Sangwuk PARK, Suwon-si (KR); Cheonggu CHO, Suwon-si (KR); Byeungmoo KANG, Suwon-si (KR); Myeonghwan SHIN, Suwon-si (KR)

(73) Assignee: SAMSUNG ELECTRONICS CO., LTD., Suwon-si (KR)

(21) Appl. No.: 19/215,987

(22) Filed: May 22, 2025

(30) Foreign Application Priority Data
Oct. 16, 2024 (KR) 10-2024-0141451

(51) Int. Cl. H10B 12/00; H10D 1/68; H10D 64/68

(52) U.S. Cl. CPC H10B 12/50; H10B 12/09; H10D 1/716; H10D 64/693

(57) ABSTRACT

A semiconductor device may include a mold structure including an etching stopper layer, a first stack including first sacrificial layers and second sacrificial layers that are alternately stacked on the etching stopper layer, a first supporter layer on the first stack, a second stack including third sacrificial layers and fourth sacrificial layers that are alternately stacked on the first supporter layer, a second supporter layer on the second stack, a third stack including fifth sacrificial layers and sixth sacrificial layers that are alternately stacked on the second supporter layer, and a third supporter layer on the third stack. The semiconductor device may further include a capacitor structure penetrating the mold structure and including a cylindrical lower electrode, a dielectric layer, and a cylindrical upper electrode, and the semiconductor device may further include a plate-shaped upper electrode on the cylindrical lower electrode, the dielectric layer, and the cylindrical upper electrode.

### CROSS-REFERENCE TO RELATED APPLICATION

This application is based on and claims priority under 35 U.S.C. § 119 to Korean Patent Application No. 10-2024-0141451, filed on Oct. 16, 2024, in the Korean Intellectual Property Office, the disclosure of which is incorporated by reference herein in its entirety.

### BACKGROUND

### 1. Field

Some embodiments of the present disclosure relate to a semiconductor device, and more particularly, to a semiconductor device including a capacitor.

### 2. Description of Background Art

As semiconductor devices, such as dynamic random-access memory (DRAM) devices, become highly integrated, sizes of capacitors of semiconductor devices are also decreasing. However, even though the sizes of capacitors decrease, same or higher values of capacitances of unit cells of semiconductor devices may be required.

In addition, as semiconductor devices become highly integrated, an aspect ratio of a through hole (or contact hole) provided in a mold structure to form lower electrodes of capacitors increases, which makes it difficult to reliably form capacitors.

### SUMMARY

According to embodiments of the present disclosure, a semiconductor device may be provided and include a mold structure capable of reliably forming a capacitor.

According to embodiments of the present disclosure, a semiconductor device may be provided and include: a substrate including a cell region; a cell conductive pad in the cell region; a mold structure on the cell conductive pad, wherein the mold structure includes: an etching stopper layer on the cell conductive pad; a first stack that includes a plurality of first sacrificial layers and a plurality of second sacrificial layers that are alternately stacked on the etching stopper layer; a first supporter layer on the first stack; a second stack including a plurality of third sacrificial layers and a plurality of fourth sacrificial layers that are alternately stacked on the first supporter layer; a second supporter layer on the second stack; a third stack including a plurality of fifth sacrificial layers and a plurality of sixth sacrificial layers that are alternately stacked on the second supporter layer; and a third supporter layer on the third stack; a capacitor structure penetrating the mold structure in the cell region, wherein the capacitor structure includes: a cylindrical lower electrode; a dielectric layer on one side wall of the cylindrical lower electrode; and a cylindrical upper electrode on one side wall of the dielectric layer; and a plate-shaped upper electrode on the cylindrical lower electrode, the dielectric layer, and the cylindrical upper electrode in the cell region.

According to embodiments of the present disclosure, a semiconductor device may be provided and include: a substrate including a cell region and a peripheral circuit region; a cell conductive pad in the cell region; a peripheral conductive pad in the peripheral circuit region; a mold structure on the cell conductive pad and the peripheral conductive pad, wherein the mold structure includes: an etching stopper layer on the cell conductive pad and the peripheral conductive pad; a first stack including a plurality of first sacrificial layers and a plurality of second sacrificial layers that are alternately stacked on the etching stopper layer; a first supporter layer on the first stack; a second stack including a plurality of third sacrificial layers and a plurality of fourth sacrificial layers that are alternately stacked on the first supporter layer; a second supporter layer on the second stack; a third stack including a plurality of fifth sacrificial layers and a plurality of sixth sacrificial layers that are alternately stacked on the second supporter layer; and a third supporter layer on the third stack; a capacitor structure penetrating the mold structure in the cell region, wherein the capacitor structure includes a cylindrical lower electrode, a dielectric layer on one side wall of the cylindrical lower electrode, and a cylindrical upper electrode on one side wall of the dielectric layer; a first peripheral metal contact layer penetrating the mold structure in the peripheral circuit region; and a plate-shaped upper electrode on the cylindrical lower electrode, the dielectric layer, and the cylindrical upper electrode in the cell region.

According to embodiments of the present disclosure, a semiconductor device may be provided and include: a substrate including a cell region and a peripheral circuit region; a cell conductive pad in the cell region; a peripheral conductive pad in the peripheral circuit region; a mold structure on the cell conductive pad, wherein the mold structure includes: an etching stopper layer on the cell conductive pad; a first stack including a plurality of first sacrificial layers and a plurality of second sacrificial layers that are alternately stacked on the etching stopper layer; a first supporter layer on the first stack; a second stack including a plurality of third sacrificial layers and a plurality of fourth sacrificial layers that are alternately stacked on the first supporter layer; a second supporter layer on the second stack; a third stack including a plurality of fifth sacrificial layers and a plurality of sixth sacrificial layers that are alternately stacked on the second supporter layer; and a third supporter layer on the third stack; a capacitor structure penetrating the mold structure in the cell region, wherein the capacitor structure includes: a cylindrical lower electrode; a dielectric layer on one side wall of the cylindrical lower electrode; and a cylindrical upper electrode on one side wall of the dielectric layer; a peripheral buried insulating layer in the peripheral circuit region; a metal contact layer penetrating the peripheral buried insulating layer in the peripheral circuit region; and a plate-shaped upper electrode on the cylindrical lower electrode, the dielectric layer, and the cylindrical upper electrode in the cell region.

### BRIEF DESCRIPTION OF DRAWINGS

Embodiments will be more clearly understood from the following detailed description taken in conjunction with the accompanying drawings in which:

FIG. 1 is a layout view of a semiconductor device according to an embodiment;

FIG. 2 is a cross-sectional view for explaining a semiconductor device according to an embodiment;

FIGS. 3 to 15, and 18 to 23 are cross-sectional views for explaining a method of manufacturing the semiconductor device of FIG. 2 according to an embodiment;

FIGS. 16 and 17 are plan views for explaining a manufacturing process of FIG. 15;

FIG. 24 is a cross-sectional view for explaining a semiconductor device according to an embodiment;

FIGS. 25 to 27 are cross-sectional views for explaining a method of manufacturing the semiconductor device of FIG. 24 according to an embodiment;

FIG. 28 is a cross-sectional view for explaining a semiconductor device according to an embodiment;

FIGS. 29 to 41 are cross-sectional views for explaining a method of manufacturing the semiconductor device of FIG. 28 according to an embodiment;

FIG. 42 is a cross-sectional view for explaining a semiconductor device according to an embodiment;

FIGS. 43 and 44 are cross-sectional views for explaining a method of manufacturing the semiconductor device of FIG. 42 according to an embodiment;

FIG. 45 is a cross-sectional view for explaining a semiconductor device according to an embodiment; and

FIGS. 46 to 48 are cross-sectional views for explaining a method of manufacturing the semiconductor device of FIG. 45 according to an embodiment.

### DETAILED DESCRIPTION

Hereinafter, non-limiting example embodiments of the present disclosure will be described in detail with reference to the accompanying drawings. The following example embodiments of the present disclosure may be implemented in only one embodiment, or may be implemented in a combination of one or more embodiments. Therefore, embodiments of the present disclosure are not limited to the example embodiments.

Herein, the singular form of the components may include a plurality of forms unless a different case is clearly indicated in the context. Herein, the drawings may be exaggerated to describe example embodiments of the present disclosure more clearly.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

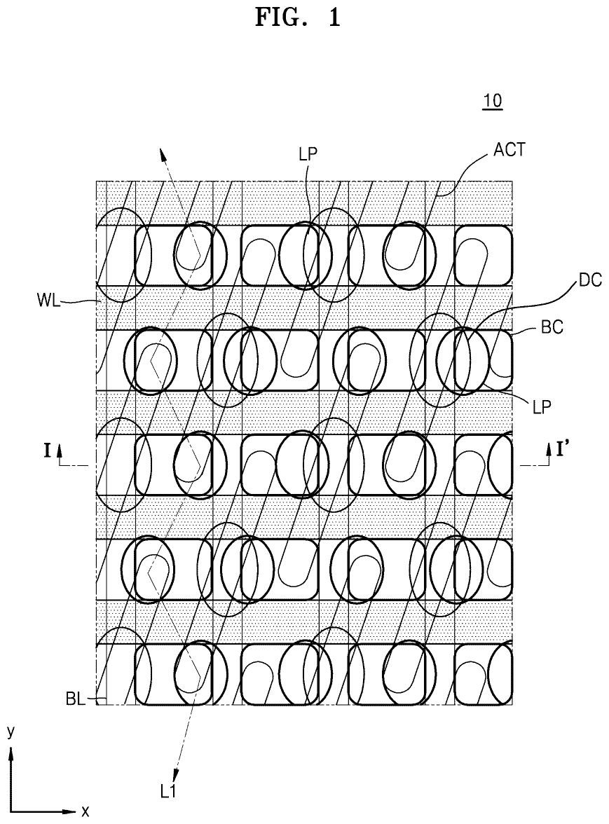

FIG. 1 is a layout view of a semiconductor device 10 according to an embodiment.

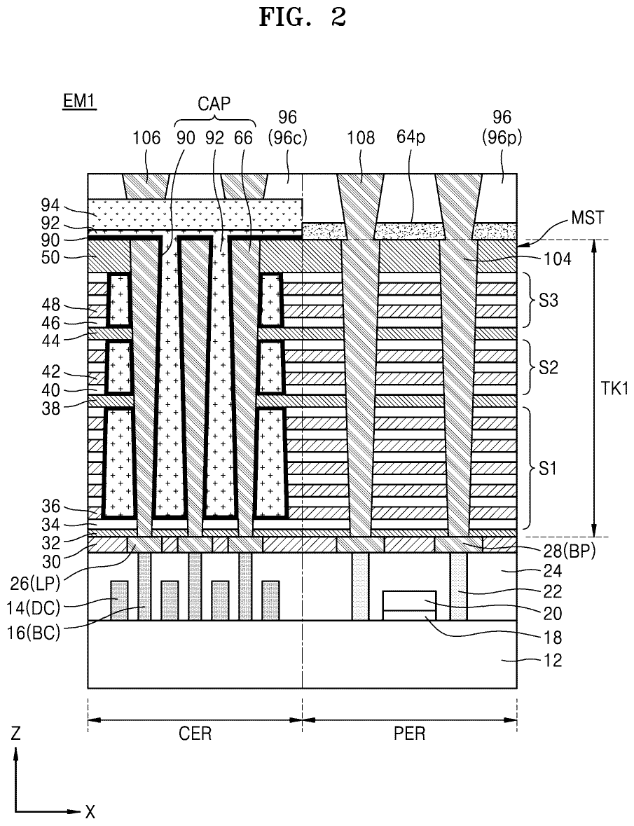

Specifically, FIG. 1 may illustrate a cell region of the semiconductor device 10. The semiconductor device 10 may be a dynamic random-access memory (DRAM) device. The semiconductor device 10 may include a plurality of active regions ACT. The active region ACT may be defined through a device isolation layer formed on a substrate 12 (see FIG. 2). As a design rule of the semiconductor device 10 decreases, the active region ACT may be disposed in the form of a bar of a diagonal line or an oblique line as shown.

A plurality of word lines WL (or gate lines) extending in parallel to each other in a first horizontal direction (e.g., X-axis direction) across the active region ACT and spaced apart from each other in a second horizontal direction (e.g., Y-axis direction) may be disposed on the active region ACT. The word lines WL may be disposed at a same interval. The width of the word line WL or the interval between the word lines WL may be determined according to a design rule. A plurality of bit lines BL extending in parallel to each other in the second horizontal direction (e.g., Y-axis direction) orthogonal to the word line WL may be disposed on the word line WL. The bit lines BL may also be disposed at an equal interval. The width of the bit line BL or the interval between the bit lines BL may be determined according to the design rule.

Each of the bit lines BL may have a pitch of 3F and be disposed parallel to each other. In addition, the word lines WL may each have a pitch of 2F and be disposed parallel to each other. Here, F may mean a minimum lithographic feature size. When the bit lines BL and the word lines WL are arranged at the pitch intervals as described above, the semiconductor device 10 may include a memory cell having a unit cell size of 6F2.

The semiconductor device 10 may include various contact arrangements formed on the active region ACT such as, for example, a direct contact DC, a buried contact BC, and a landing pad LP. Here, the direct contact DC may mean a contact connecting the active region ACT to the bit line BL, and the buried contact BC may mean a contact connecting the active region ACT to a lower electrode of the capacitor.

Due to an arrangement structure, the contact area between the buried contact BC and the active region ACT may be very small. Accordingly, a landing pad LP, which may be conductive, may be introduced to increase the contact area between the active region ACT and the lower electrode of the capacitor. The landing pad LP may be disposed between the active region ACT and the buried contact BC, or between the buried contact BC and the lower electrode of the capacitor. By expanding the contact area through the introduction of the landing pad LP as described above, the contact resistance between the active region ACT and the lower electrode of the capacitor may be reduced.

In the semiconductor device 10, the direct contact DC may be disposed at a central part of the active region ACT, and buried contacts BC may be disposed at both end parts of the active region ACT. As the buried contacts BC are disposed at both end parts of the active region ACT, landing pads LP may be disposed adjacent to both ends of the active region ACT to partially overlap the buried contacts BC.

The word line WL may be formed in a buried structure in the substrate 12 of FIG. 2 of the semiconductor device 10, and may be disposed across the active region ACT between the direct contacts DC or the buried contacts BC. As shown, two word lines WL may be disposed to cross one active region ACT, and the active region ACT may be disposed in a diagonal shape, so that the word line WL and the active region ACT may have a certain angle of less than 90°.

The direct contact DC and the buried contact BC may be symmetrically disposed and, accordingly, may be disposed on a straight line in the first horizontal direction (e.g., X-axis direction) and the second horizontal direction (e.g., Y-axis direction). Unlike the direct contact DC and the buried contact BC, the landing pads LP may be arranged in a zigzag shape L1 in the second horizontal direction (e.g., Y-axis direction) in which the bit line BL extends. In addition, the landing pads LP may be disposed in the first horizontal direction (e.g., X-axis direction) in which the word line WL extends to overlap the same side part of each bit line BL. For example, each of the landing pads LP in a first line may overlap a left side of the corresponding bit line BL, and each of the landing pads LP in a second line may overlap a right side of the corresponding bit line BL.

FIG. 2 is a cross-sectional view for explaining a semiconductor device EM1 according to an embodiment.

Specifically, the semiconductor device EM1 may include the substrate 12 having a cell region CER and a peripheral circuit region PER. FIG. 2 may show, in part, a cross-sectional view of a cell region CER, which may be a cross-sectional view taken along a line I-I′ of FIG. 1. A cell transistor may be formed on the substrate 12 in the cell region CER. The peripheral circuit region PER may include devices for operating the cell region CER such as, for example, a peripheral circuit transistor.

In some embodiments, the peripheral circuit region PER may be formed on a separate substrate and bonded to the cell region CER. In some embodiments, a capacitor structure (or a capacitor) may be manufactured on the separate substrate. The capacitor structure manufactured on the separate substrate may be bonded (or joined) to the cell transistor in the cell region CER of FIG. 1. Bonding portions (or joining portions) bonded to the capacitor structure and the cell transistor may be copper pads or conductive pads.

A first contact 14 and a second contact 16 may be disposed on the substrate 12 in the cell region CER. The substrate 12 may be a silicon substrate. The first contact 14 may be the direct contact DC shown in FIG. 1. The second contact 16 may be the buried contact BC shown in FIG. 1. A word line or a cell impurity region may be formed inside the substrate 12 in the cell region CER as described with reference to FIG. 1.

A peripheral gate insulating layer 18 and a peripheral gate electrode 20 may be disposed on the substrate 12 in the peripheral circuit region PER. A peripheral impurity region may be disposed inside the substrate 12 in the peripheral circuit region PER. The peripheral gate insulating layer 18 and the peripheral gate electrode 20 may constitute a peripheral transistor. A third contact 22 may be disposed on the substrate 12 in the peripheral circuit region PER. An upper end of third contact 22 may be disposed at a same height as a height of an upper end of the second contact 16 in the cell region CER.

A first insulating layer 24 may be formed to insulate the first contact 14 and the second contact 16 in the cell region CER, and to insulate the peripheral gate insulating layer 18, the peripheral gate electrode 20, and the third contact 22 in the peripheral circuit region PER.

A cell conductive pad 26 connected to the second contact 16 may be disposed in the cell region CER. The cell conductive pad 26 may be the landing pad LP of FIG. 1. A peripheral conductive pad 28 connected to the third contact 22 in the peripheral circuit region PER may be disposed. The peripheral conductive pad 28 may be a buried pad BP. The peripheral conductive pad 28 may be a bonding pad. The cell conductive pad 26 and the peripheral conductive pad 28 may be insulated from each other by the second insulating layer 30. The second insulating layer 30 may be configured as a silicon nitride layer.

A mold structure MST may be disposed on the cell conductive pad 26, the peripheral conductive pad 28, and the second insulating layer 30. The mold structure MST may include an etching stopper layer 32, and a first stack S1 in which a plurality of first sacrificial layers 34 and a plurality of second sacrificial layers 36 are alternately stacked on the etching stopper layer 32.

The mold structure MST may further include a first supporter layer 38 disposed on the first stack S1, and a second stack S2 in which a plurality of third sacrificial layers 40 and a plurality of fourth sacrificial layers 42 are alternately stacked on the first supporter layer 38. The mold structure MST may further include a second supporter layer 44 disposed on the second stack S2, a third stack S3 in which a plurality of fifth sacrificial layers 46 and a plurality of sixth sacrificial layers 48 are alternately stacked on the second supporter layer 44, and a third supporter layer 50 disposed on the third stack S3.

In some embodiments, the first sacrificial layer 34, the third sacrificial layer 40, and the fifth sacrificial layer 46 may include the same material as each other. The second sacrificial layer 36, the fourth sacrificial layer 42, and the sixth sacrificial layer 48 may include the same material as each other. The first sacrificial layer 34, the third sacrificial layer 40, and the fifth sacrificial layer 46 may include materials having different etching speeds (or etching rates) from materials of the second sacrificial layer 36, the fourth sacrificial layer 42, and the sixth sacrificial layer 48.

In some embodiments, each of the first sacrificial layer 34, the third sacrificial layer 40, and the fifth sacrificial layer 46 may be formed as a silicon oxide layer. Each of the second sacrificial layer 36, the fourth sacrificial layer 42, and the sixth sacrificial layer 48 may be formed as a silicon nitride layer. In some embodiments, the etching stopper layer 32, the first supporter layer 38, the second supporter layer 44, and the third supporter layer 50 may include materials having lower etching rates than materials of the first to sixth sacrificial layers 34, 36, 40, 42, 46, and 48. In some embodiments, the etching stopper layer 32, the first supporter layer 38, the second supporter layer 44, and the third supporter layer 50 may include SiBN, SiOCN, SiON, or SiCN.

A capacitor structure CAP penetrating the mold structure MST and connected to the cell conductive pad 26 may be disposed in the cell region CER. The capacitor structure CAP may include at least one cylindrical lower electrode 66, a dielectric layer 90, and a cylindrical upper electrode 92. The cylindrical lower electrode 66 may be formed on the cell conductive pad 26.

The dielectric layer 90 may surround the cylindrical lower electrode 66. The dielectric layer 90 may be formed on one side of the cylindrical lower electrode 66. The dielectric layer 90 may be formed on upper surfaces or lower surfaces of the first supporter layer 38, the second supporter layer 44, and the third supporter layer 50. The cylindrical upper electrode 92 may be disposed on the dielectric layer 90. The cylindrical upper electrode 92 may be disposed between a plurality of cylindrical lower electrodes 66 on the dielectric layer 90.

Each of the cylindrical lower electrode 66 and the cylindrical upper electrode 92 may include a titanium nitride layer TiN. The mold structure MST may be removed between the cylindrical lower electrodes 66 in the cell region CER. A part of the mold structure MST may remain in an edge part of the cell region CER, a left edge part of FIG. 2, or near a boundary between the cell region CER and the peripheral circuit region PER.

At least one first peripheral metal contact layer 104 penetrating the mold structure MST and connected to the peripheral conductive pad 28 may be disposed in the peripheral circuit region PER. The capacitor structure CAP and the first peripheral metal contact layer 104 may have the same height TK1. A plate-shaped upper electrode 94 may be disposed on the cylindrical lower electrodes 66, the dielectric layer 90, and the cylindrical upper electrode 92 in the cell region CER. A lower surface of the plate-shaped upper electrode 94 may have the same height as a lower surface of the first peripheral metal contact layer 104 in the peripheral circuit region PER. The lower surface of the plate-shaped upper electrode 94 may be higher or lower than the lower surface of the first peripheral metal contact layer 104 in the peripheral circuit region PER. The plate-shaped upper electrode 94 may also be filled in a gap between the cylindrical upper electrodes 92 when the gap occurs between the cylindrical upper electrodes 92.

A first peripheral interlayer insulating layer 64p may be disposed on the third supporter layer 50 of the mold structure MST, in the peripheral circuit region PER. A second interlayer insulating layer 96 may be disposed on the plate-shaped upper electrode 94 in the cell region CER and the first peripheral interlayer insulating layer 64p in the peripheral circuit region PER. The second interlayer insulating layer 96 may include a second cell interlayer insulating layer 96c formed in the cell region CER and a second peripheral interlayer insulating layer 96p formed in the peripheral circuit region PER.

The cell region CER may include a cell metal contact layer 106, connected to the plate-shaped upper electrode 94, in the second cell interlayer insulating layer 96c. The peripheral circuit region PER may include a second peripheral metal contact layer 108 connected to the first peripheral metal contact layer 104.

The semiconductor device EM1 configured as described above may easily form the capacitor structure CAP formed on the mold structure MST, especially the cylindrical lower electrode 66. Accordingly, the semiconductor device EM1 may reliably form the capacitor structure CAP (or a capacitor).

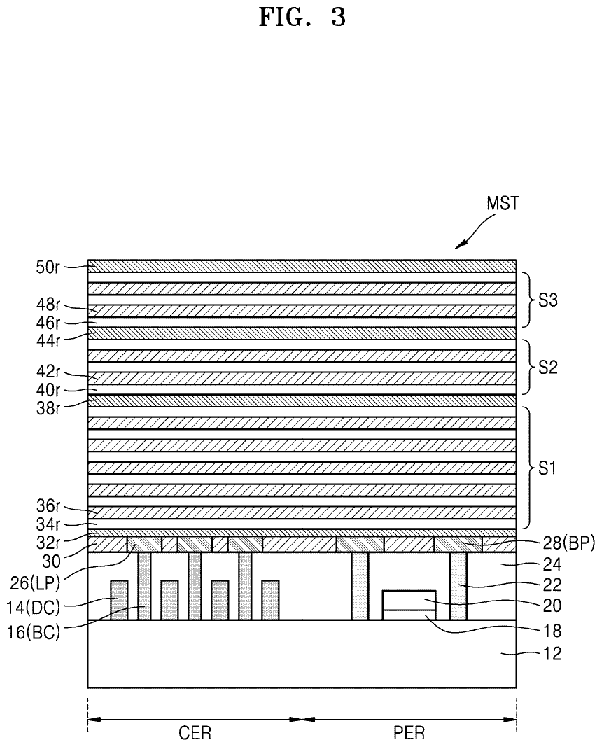

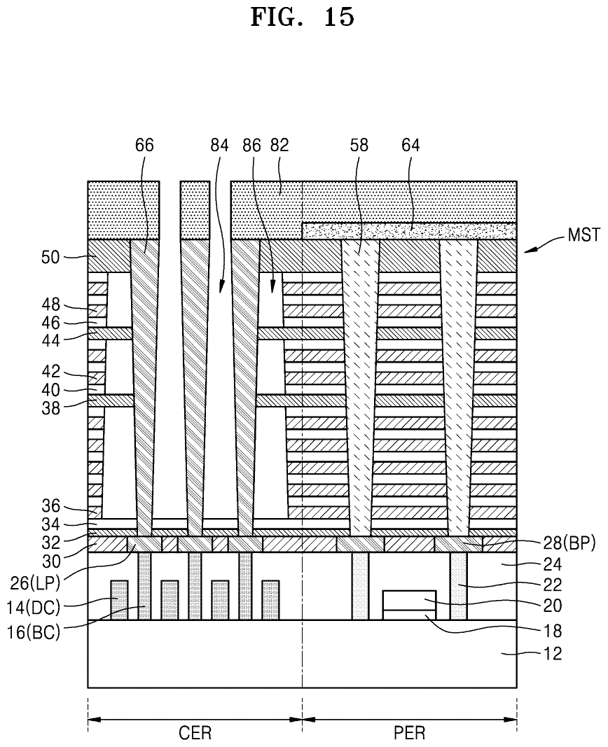

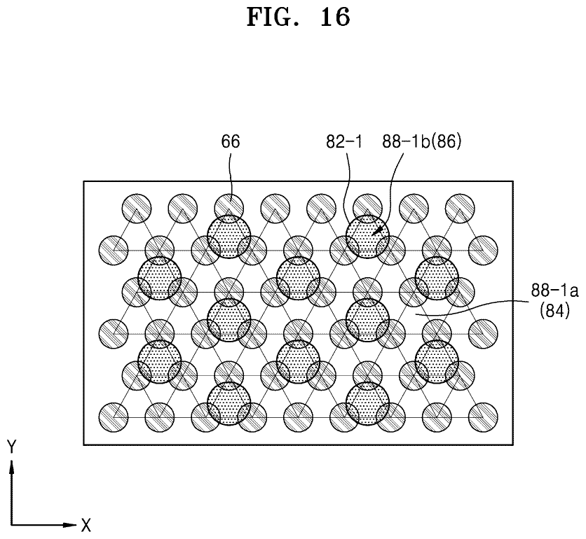

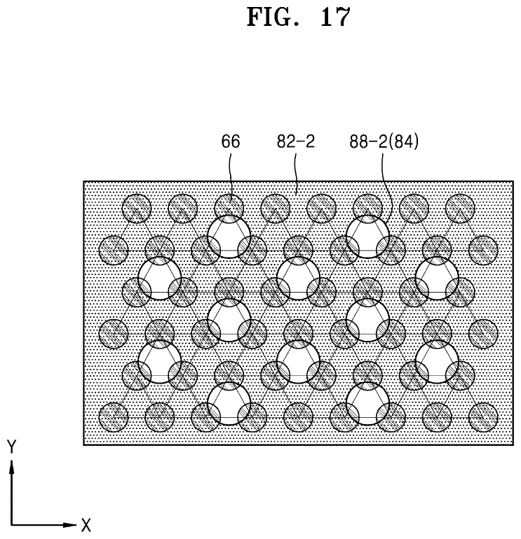

FIGS. 3 to 15 and 18 to 23 are cross-sectional views for explaining a method of manufacturing the semiconductor device of FIG. 2 according to an embodiment, and FIGS. 16 and 17 are plan views for explaining a manufacturing process of FIG. 15.

Specifically, in FIGS. 3 to 23, the same reference numerals as in FIG. 2 denote the same members. For FIGS. 3 to 23, descriptions given with reference to FIG. 2 may be briefly described or omitted.

Referring to FIG. 3, the first contact 14 and the second contact 16 may be formed on the substrate 12 in the cell region CER. The peripheral gate insulating layer 18, the peripheral gate electrode 20, and the third contact 22 may be formed on the substrate 12 in the peripheral circuit region PER. The first insulating layer 24 may be formed to insulate the first contact 14 and the second contact 16 in the cell region CER, and the peripheral gate insulating layer 18, the peripheral gate electrode 20, and the third contact 22 in the peripheral circuit region PER.

The cell conductive pad 26 connected to the second contact 16 may be formed in the cell region CER. The peripheral conductive pad 28 connected to the third contact 22 may be formed on the peripheral circuit region PER. The second insulating layer 30 may be formed to insulate the cell conductive pad 26 and the peripheral conductive pad 28. The second insulating layer 30 may be formed as a silicon nitride layer.

The mold structure MST may be formed on the cell conductive pad 26, the peripheral conductive pad 28, and the second insulating layer 30. The mold structure MST may include an etching stopper material layer 32r and the first stack S1, in which a plurality of first sacrificial material layers 34r and a plurality of second sacrificial material layers 36r are alternately stacked on the etching stopper material layer 32r.

The mold structure MST may further include a first supporter material layer 38r disposed on the first stack S1, and the second stack S2 in which a plurality of third sacrificial material layers 40r and a plurality of fourth sacrificial material layers 42r are alternately stacked on the first supporter material layer 38r.

The mold structure MST may further include a second supporter material layer 44r disposed on the second stack S2, the third stack S3 in which a plurality of fifth sacrificial material layers 46r and a plurality of sixth sacrificial material layers 48r are alternately stacked on the second supporter material layer 44r, and a third supporter material layer 50r disposed on the third stack S3.

Each of the first to sixth sacrificial material layers 34r, 36r, 40r, 42r, 46r, 48r, and the first to third supporter material layers 38r, 44r and 50r constituting the mold structure MST may include a film material which is advantageous for a subsequent etching process. Each of the first to sixth sacrificial material layers 34r, 36r, 40r, 42r, 46r, 48r, and the first to third supporter material layers 38r, 44r, and 50r constituting the mold structure MST may have a thickness which is advantageous for the subsequent etching process. For example, each of the first to sixth sacrificial material layers 34r, 36r, 40r, 42r, 46r, 48r, and the first to third supporter material layers 38r, 44r, and 50r constituting the mold structure MST may have a thickness of tens to hundreds of Å.

More specifically, in some embodiments, the first stack S1, the second stack S2, and the third stack S3 constituting the mold structure MST may have different thicknesses from each other. For example, the first stack S1 may have a larger or smaller thickness than a thickness of each of the second stack S2 and the third stack S3.

In some embodiments, the first sacrificial material layer 34r, the third sacrificial material layer 40r, and the fifth sacrificial material layer 46r may include the same material as each other. The second sacrificial material layer 36r, the fourth sacrificial material layer 42r, and the sixth sacrificial material layer 48r may include the same material as each other.

The first sacrificial material layer 34r, the third sacrificial material layer 40r, and the fifth sacrificial material layer 46r may include materials having different etching speeds (or etching rates) from materials of the second sacrificial material layer 36r, the fourth sacrificial material layer 42r, and the sixth sacrificial material layer 48r. Each of the first to sixth sacrificial material layers 34r, 36r, 40r, 42r, 46r and 48r may include a film material that is advantageous for the subsequent etching process.

In some embodiments, each of the first sacrificial material layer 34r, the third sacrificial material layer 40r, and the fifth sacrificial material layer 46r may be formed as a silicon oxide layer. Each of the second sacrificial material layer 36r, the fourth sacrificial material layer 42r, and the sixth sacrificial material layer 48r may be formed as a silicon nitride layer.

In some embodiments, the silicon nitride layer constituting the second sacrificial material layer 36r may have a different nitrogen concentration from a nitrogen concentration of the silicon nitride layer constituting each of the fourth sacrificial material layer 42r and the sixth sacrificial material layer 48r. For example, the silicon nitride layer constituting the second sacrificial material layer 36r may have a larger or smaller nitrogen concentration than a nitrogen concentration of the silicon nitride layer constituting each of the fourth sacrificial material layer 42r and the sixth sacrificial material layer 48r.

In some embodiments, the first sacrificial material layer 34r, the third sacrificial material layer 40r, and the fifth sacrificial material layer 46r may respectively have the same thicknesses as the second sacrificial material layer 36r, the fourth sacrificial material layer 42r, and the sixth sacrificial material layer 48r.

In some embodiments, the first sacrificial material layer 34r, the third sacrificial material layer 40r, and the fifth sacrificial material layer 46r may respectively have different thicknesses from the second sacrificial material layer 36r, the fourth sacrificial material layer 42r, and the sixth sacrificial material layer 48r. For example, the first sacrificial material layer 34r, the third sacrificial material layer 40r, and the fifth sacrificial material layer 46r may be respectively thicker or thinner than the second sacrificial material layer 36r, the fourth sacrificial material layer 42r, and the sixth sacrificial material layer 48r.

In some embodiments, the third sacrificial material layer 40r and the fifth sacrificial material layer 46r may respectively have the same thicknesses as thicknesses of the fourth sacrificial material layer 42r and the sixth sacrificial material layer 48r, and the second sacrificial material layer 36r may have a greater thickness than a thickness of the first sacrificial material layer 34r.

In some embodiments, the etching stopper material layer 32r, the first supporter material layer 38r, the second supporter material layer 44r, and the third supporter material layer 50r may include materials having lower etching speeds than materials of the first to sixth sacrificial material layers 34r, 36r, 40r, 42r, 46r, and 48r.

In some embodiments, the first supporter material layer 38r, the second supporter material layer 44r, and the third supporter material layer 50r may have the same thickness as each other. In some embodiments, the third supporter material layer 50r may have a greater thickness than a thickness of each of the first supporter material layer 38r and the second supporter material layer 44r, and the first supporter material layer 38r and the second supporter material layer 44r may have the same thickness as each other. In some embodiments, the third supporter material layer 50r may be thicker than the second supporter material layer 44r, and the second supporter material layer 44r may be thicker than the first supporter material layer 38r.

In some embodiments, the first supporter material layer 38r, the second supporter material layer 44r, and the third supporter material layer 50r may have the same thicknesses as thicknesses of the first to sixth sacrificial material layers 34r, 36r, 40r, 42r, 46r, and 48r. In some embodiments, the first supporter material layer 38r, the second supporter material layer 44r, and the third supporter material layer 50r may have larger or smaller thicknesses than thicknesses of the first to sixth sacrificial material layers 34r, 36r, 40r, 42r, 46r, and 48r.

In some embodiments, each of the etching stopper material layer 32r, the first supporter material layer 38r, the second supporter material layer 44r, and the third supporter material layer 50r may include SiBN, SiOCN, SiCN, or SiCBN.

In some embodiments, each of the etching stopper material layer 32r, the first supporter material layer 38r, the second supporter material layer 44r, and the third supporter material layer 50r may include a combination of C, B, N, and/or O elements in a silicon material.

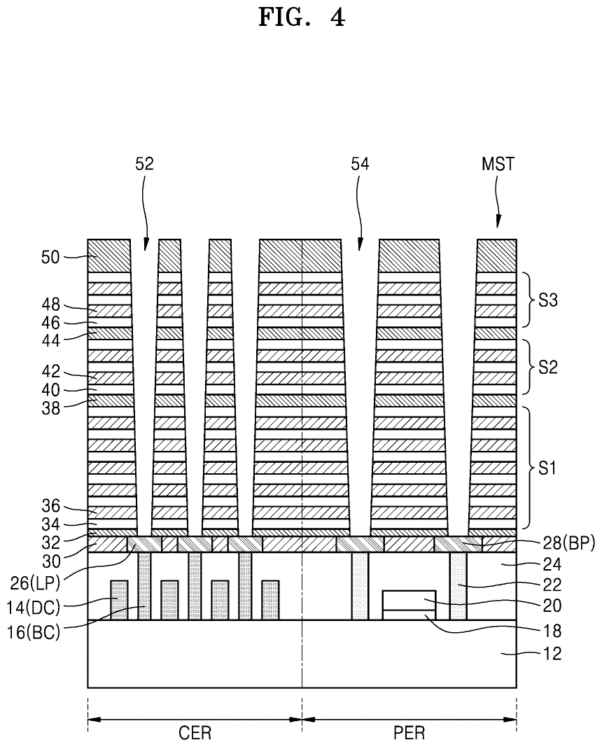

Referring to FIG. 4, at least one first through hole 52 and at least one second through hole 54 may be formed on the cell conductive pad 26 and the peripheral conductive pad 28, respectively, by etching the mold structure MST through a photolithography process. The first through hole 52 and the second through hole 54 may expose the cell conductive pad 26 and the peripheral conductive pad 28, respectively. The first through hole 52 and the second through hole 54 may be formed through a dry etching process using plasma.

In some embodiments, when the first through hole 52 and the second through hole 54 are formed, the mold structure MST may be simultaneously formed through a single etching process. In some embodiments, when the first through hole 52 and the second through hole 54 are formed, the mold structure MST may be divided and etched step by step. For example, when the first through hole 52 and the second through hole 54 are formed, the third supporter material layer 50r may be primarily etched, the third stack S3 in FIG. 3 and the second supporter material layer 44r may be secondarily etched, the second stack S2 in FIG. 3 and the first supporter material layer 38r may be thirdly etched, and a part of the first stack S1 in FIG. 3 on the etching stopper material layer 32r may be fourthly etched.

When the first through hole 52 and the second through hole 54 are formed, the mold structure MST may include the etching stopper layer 32 and the first stack S1 in which the plurality of first sacrificial layers 34 and the plurality of second sacrificial layers 36 are alternately stacked on the etching stopper layer 32. The etching stopper material layer 32r of FIG. 3, the first sacrificial material layer 34r of FIG. 3, and the second sacrificial material layer 36r of FIG. 3 may become the etching stopper layer 32, the first sacrificial layer 34, and the second sacrificial layer 36, respectively.

The mold structure MST may include the first supporter layer 38 disposed on the first stack S1, and the second stack S2 in which the plurality of third sacrificial layers 40 and the plurality of fourth sacrificial layers 42 are alternately stacked on the first supporter layer 38. The first supporter material layer 38r of FIG. 3, the third sacrificial material layer 40r of FIG. 3, and the fourth sacrificial material layer 42r of FIG. 3 may become the first supporter layer 38, the third sacrificial layer 40, and the fourth sacrificial layer 42, respectively.

The mold structure MST may include the second supporter layer 44 disposed on the second stack S2, the third stack S3 in which the plurality of fifth sacrificial layers 46 and the plurality of sixth sacrificial layers 48 are alternately stacked on the second supporter layer 44, and the third supporter layer 50 disposed on the third stack S3.

The second supporter material layer 44r of FIG. 3, the fifth sacrificial layer material layer 46r of FIG. 3, the sixth sacrificial material layer 48r of FIG. 3, and the third supporter material layer 50r of FIG. 3 may become the second supporter layer 44, the fifth sacrificial layer 46, the sixth sacrificial layer 48, and the third supporter layer 50, respectively.

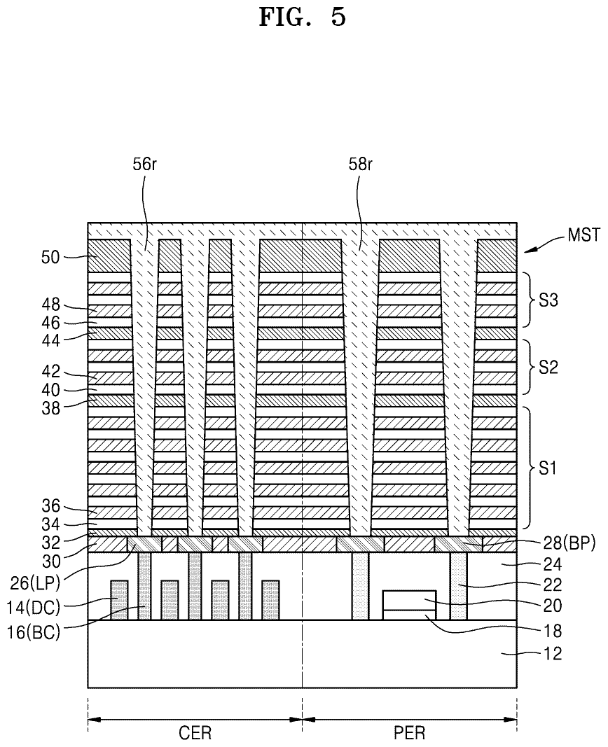

Referring to FIGS. 5 to 7, a cell buried sacrificial material layer 56r may be formed to fill the first through hole(s) 52 in FIG. 4 in the cell region CER, as shown in FIG. 5. peripheral buried sacrificial material layer 58r may be formed to fill the second through hole(s) 54 of FIG. 4 in the peripheral circuit region PER. The cell buried sacrificial material layer 56r and the peripheral buried sacrificial material layer 58r may be formed in the same process as each other. In some embodiments, each of the cell buried sacrificial material layer 56r and the peripheral buried sacrificial material layer 58r may be formed as a carbon layer.

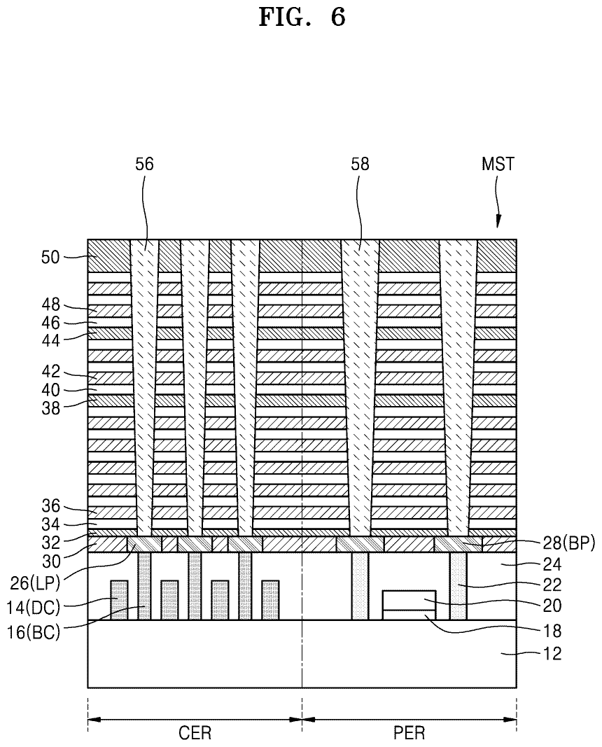

As shown in FIG. 6, a cell buried sacrificial layer 56 and a peripheral buried sacrificial layer 58 may be formed by planarizing the cell buried sacrificial material layer 56r of FIG. 5 and the peripheral buried sacrificial material layer 58r of FIG. 5 through a chemical mechanical polishing method. The cell buried sacrificial layer 56 and the peripheral buried sacrificial layer 58 may be in the first through hole 52 of FIG. 4 and the second through hole 54 of FIG. 4, respectively.

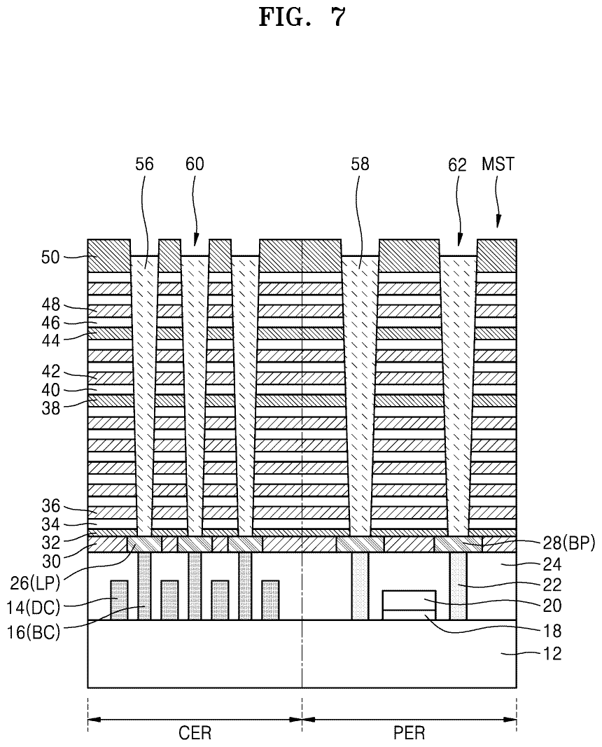

As shown in FIG. 7, in some embodiments, at least one cell sacrificial recess hole 60 and at least one peripheral sacrificial recess hole 62 may be respectively formed by further etching upper ends of the cell buried sacrificial layer 56 of FIG. 6 and the peripheral buried sacrificial layer 58 of FIG. 6. Through such a process, the cell buried sacrificial layer 56 and the peripheral buried sacrificial layer 58 may be additionally adjusted.

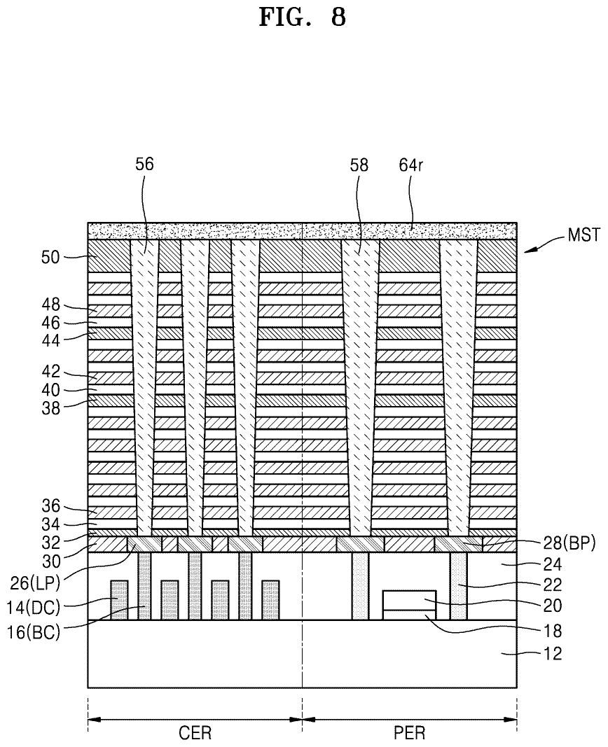

As shown in FIG. 8, a first interlayer insulating material layer 64r may be formed on the mold structure MST, the cell buried sacrificial layer 56, and the peripheral buried sacrificial layer 58. The first interlayer insulating material layer 64r may be formed as a silicon oxide layer.

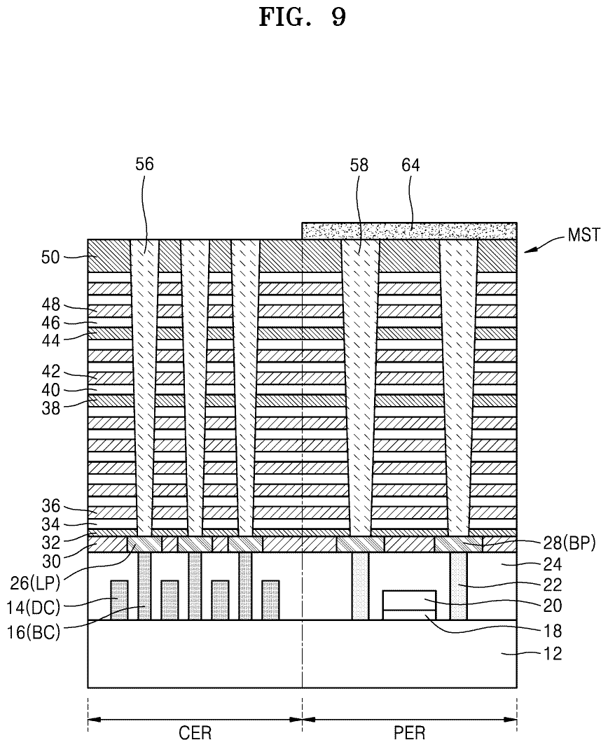

As shown in FIG. 9, a first peripheral interlayer insulating layer 64 may be formed on the mold structure MST and the peripheral buried sacrificial layer 58 in the peripheral circuit region PER by etching the first interlayer insulating material layer 64r of FIG. 8 through a photolithography process. A portion of the mold structure MST and the cell buried sacrificial layer 56 in the cell region CER may be exposed to the outside by the formation of the first peripheral interlayer insulating layer 64.

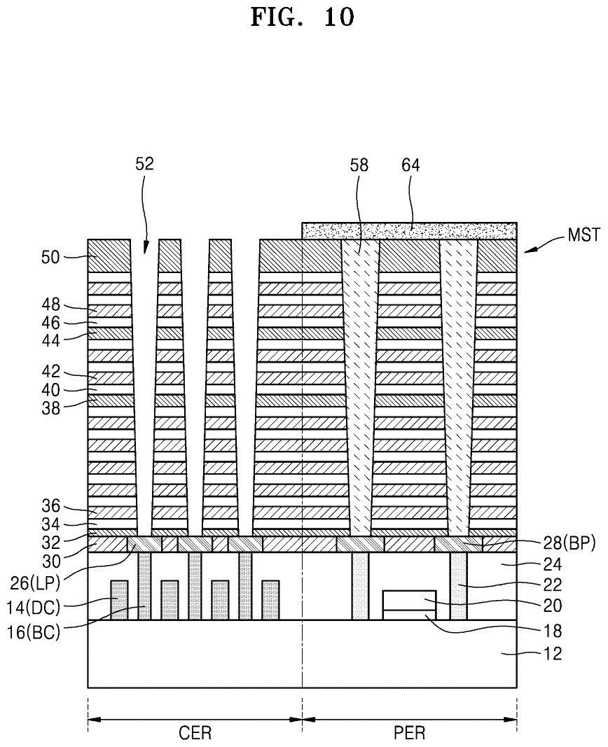

As shown in FIG. 10, the cell buried sacrificial layer 56 in FIG. 9 in the cell region CER may be removed from the first through hole(s) 52. The cell conductive pad(s) 26 in the cell region CER may be exposed according to the removal of the cell buried sacrificial layer 56.

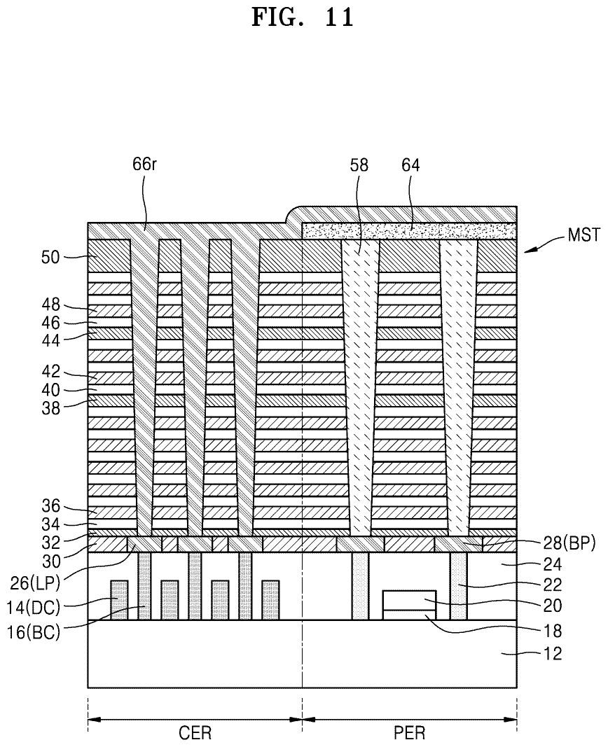

As shown in FIG. 11, a first conductive layer 66r may be formed on the mold structure MST and the first peripheral interlayer insulating layer 64 to fill the first through hole(s) 52 in the cell region CER. The first conductive layer 66r may be formed as a titanium nitride layer TiN.

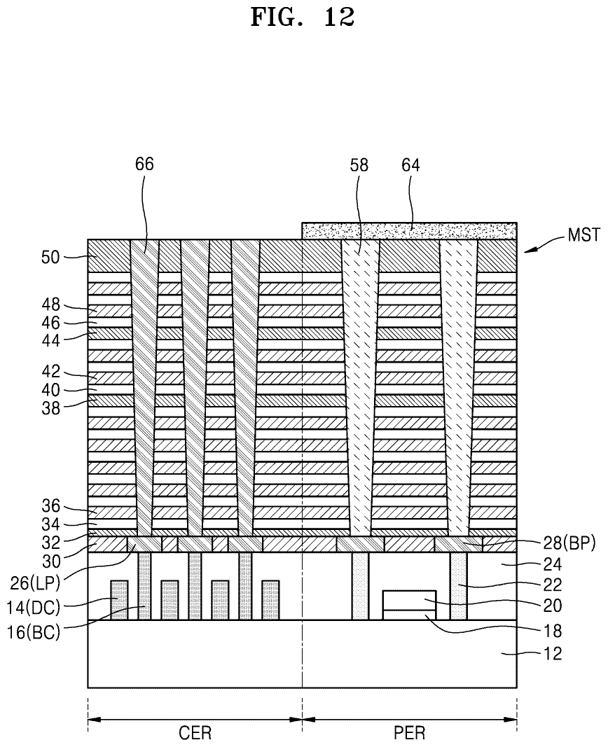

As shown in FIG. 12, at least one cylindrical lower electrode 66 in the first through hole(s) 52 in the cell region CER may be formed by etching back the first conductive layer 66r. The cylindrical lower electrode(s) 66 may be connected to the cell conductive pad(s) 26 in the cell region CER.

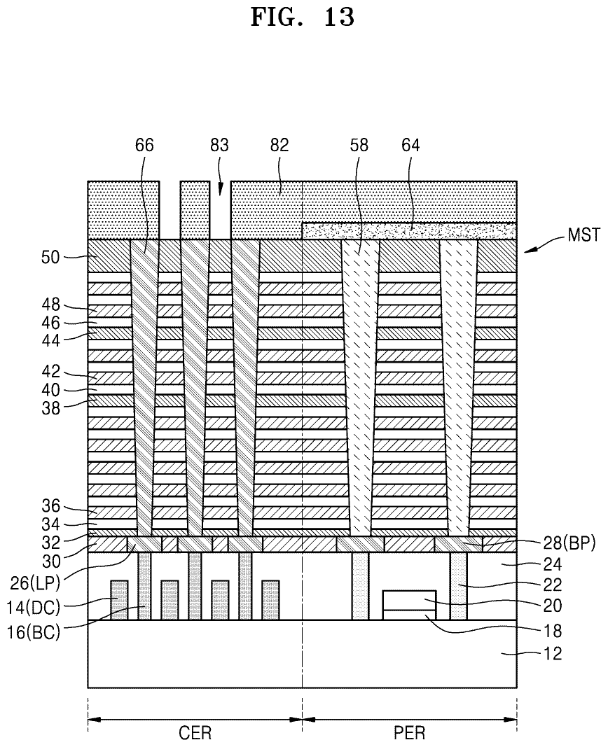

As shown in FIG. 13, a first hard mask layer 82 may be formed on the mold structure MST, the cylindrical lower electrode(s) 66, and the first peripheral interlayer insulating layer 64. The first hard mask layer 82 may include at least one mold exposure hole 83 exposing the mold structure MST in the cell region CER. The first hard mask layer 82 may be formed on the cylindrical lower electrode(s) 66 and the first peripheral interlayer insulating layer 64.

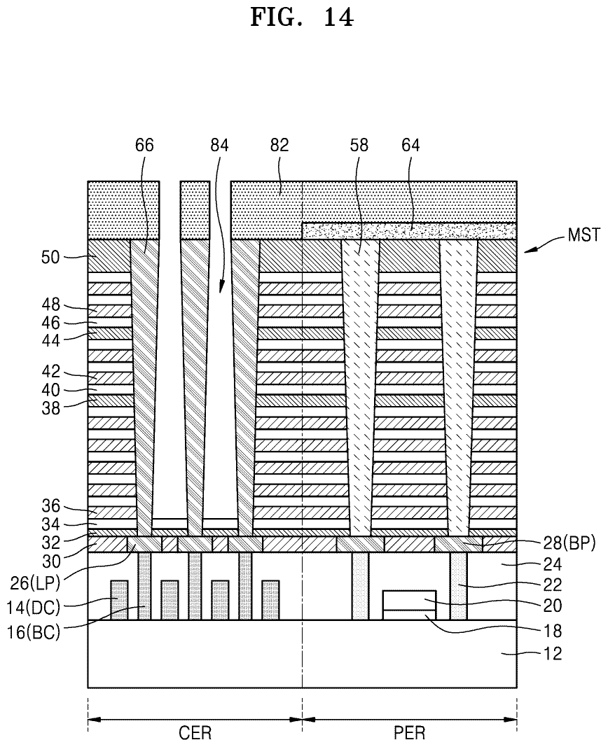

As shown in FIG. 14, at least one first etching hole 84 may be formed between the cylindrical lower electrodes 66 by etching the mold structure MST in the cell region CER by using the first hard mask layer 82 as an etching mask. The first etching hole 84 may be formed by etching a portion of the mold structure MST in the cell region CER exposed by the mold exposure hole(s) 83. The first etching hole 84 may be formed through a dry etching process using plasma.

In FIG. 14, the bottom of the first etching hole 84(s) may be an upper surface of the first sacrificial layer 34 in the mold structure MST. In some embodiments, the bottom of the first etching hole(s) 84 may be an upper surface of the etching stopper layer 32 in the mold structure MST. In some embodiments, the bottom of the first etching hole(s) 84 may be an upper surface of the first sacrificial layer 34, the second sacrificial layer 36, or the etching stopper layer 32 in the mold structure MST.

In some embodiments, when the first etching hole(s) 84 is formed, the mold structure MST may be etched through a single etching process. In some embodiments, when the first etching hole(s) 84 is formed, the mold structure MST may be divided and etched step by step. For example, when the first etching hole(s) 84 is formed, the third supporter layer 50 may be primarily etched, the third stack S3 in FIG. 3 and the second supporter layer 44 may be secondarily etched, the second stack S2 in FIG. 3 and the first supporter layer 38 may be thirdly etched, and a part of the first stack S1 in FIG. 3 on the etching stopper layer 32 may be fourthly etched.

As shown in FIG. 15, at least one second etching hole 86 may be formed in a lower portion of the first hard mask layer 82. The second etching hole(s) 86 may be formed at one side of the cylindrical lower electrode(S) 66 by additionally etching the mold structure MST in the lower portion of the first hard mask layer 82. The second etching hole(s) 86 may be formed in a lower portion of the third supporter layer 50, a lower portion of the second supporter layer 44, and a lower portion of the first supporter layer 38.

In some embodiments, the second etching hole(s) 86 may be formed through a wet etching process. Accordingly, one sidewall of each of the first to sixth sacrificial layers 34, 36, 40, 42, 46, and 48 in the second etching hole(s) 86 may have an uneven structure in a vertical direction according to a difference in etching speed between the first sacrificial layer 34 and the second sacrificial layer 36, a difference in etching speed between the third sacrificial layer 40 and the fourth sacrificial layer 42, and a difference in etching speed between the fifth sacrificial layer 46 and the sixth sacrificial layer 48.

In some embodiments, the second etching hole 86 may be formed on one side of the cylindrical lower electrode(s) 66 by removing the first hard mask layer 82 and further etching the mold structure MST. In FIG. 15, the bottom of the second etching hole(s) 86 may be an upper surface of the first sacrificial layer 34 in the mold structure MST. In some embodiments, the bottom of the second etching hole(s) 86 may be an upper surface of the etching stopper layer 32 in the mold structure MST.

Through the processes of FIGS. 14 and 15, a part of the mold structure MST may be removed between the cylindrical lower electrodes 66, and a part of the mold structure MST may remain in an edge part of the cell region CER, a left edge part of FIG. 15, or the cell region CER near a boundary between the cell region CER and the peripheral circuit region PER.

Here, the formation of the first etching hole(s) 84 and the second etching hole(s) 86 in the cell region CER will be described with reference to FIGS. 16 and 17.

Specifically, FIGS. 16 and 17 may be a planar layout of a cell region. As shown in FIGS. 16 and 17, the plurality of cylindrical lower electrodes 66 spaced apart from each other may be disposed on the substrate 12 in FIG. 15.

In some embodiments, a first hard mask layer 82-1 may be disposed on the cylindrical lower electrodes 66 as shown in FIG. 16. The first hard mask layer 82-1 may correspond to the first hard mask layer 82 of FIG. 15. A portion 88-1a exposed by the first hard mask layer 82-1 may be a portion corresponding to the first etching hole 84 of FIG. 14. An etching solution may be introduced into the first etching hole 84 of FIG. 16 so that the sacrificial layers 34, 36, 40, 42, 46, and 48 may be etched by a lift-off method in a plan view. A portion 88-1b which is not exposed by the first hard mask layer 82-1 may be a portion corresponding to the second etching hole 86 of FIG. 15.

In the manufacturing process of FIG. 14, the first etching hole 84 may be formed by etching the mold structure MST exposed by the first hard mask layer 82-1 using the first hard mask layer 82-1 as an etching mask. Subsequently, in the manufacturing process of FIG. 15, the second etching hole 86 may be formed by additionally supplying an etching solution through the first etching hole 84 and further etching the mold structure MST located in a lower portion of the first hard mask layer 82-1. Accordingly, a part of the mold structure MST may be removed between the cylindrical lower electrodes 66 in a plan view.

In some embodiments, a first hard mask layer 82-2 may be disposed on the cylindrical lower electrodes 66 as shown in FIG. 17. The first hard mask layer 82-2 may correspond to the first hard mask layer 82 of FIG. 15. A portion 88-2 exposed by the first hard mask layer 82-2 may be a portion corresponding to the first etching hole 84 of FIG. 14. An etching solution may be introduced into the first etching hole 84 of FIG. 17 so that the sacrificial layers 34, 36, 40, 42, 46, and 48 may be etched by a lift-off method in a plan view.

In the manufacturing process of FIG. 14, the at least one first etching hole 84 may be formed by etching the mold structure MST exposed by the first hard mask layer 82-2 using the first hard mask layer 82-2 as an etching mask. Subsequently, in the manufacturing process of FIG. 15, at least one second etching hole 86 may be formed by additionally supplying an etching solution through the at least one first etching hole 84 and further etching the mold structure MST located in a lower portion of the first hard mask layer 82-2. Accordingly, a portion of the mold structure MST may be removed between the cylindrical lower electrodes 66 in a plan view.

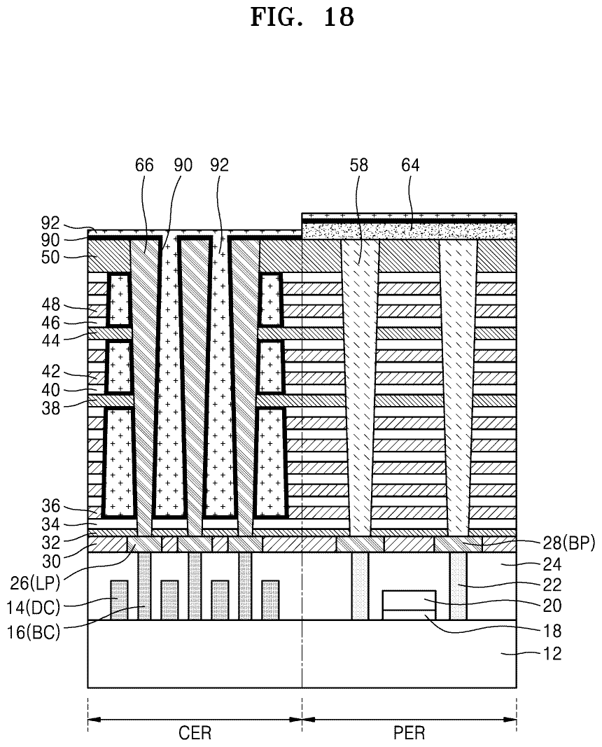

As shown in FIG. 18, after the first hard mask layer 82 is removed, a dielectric layer 90 and a cylindrical upper electrode 92 may be formed on the cylindrical lower electrodes 66 inside the first etching hole(s) 84 and the second etching hole(s) 86 in the cell region CER.

In some embodiments, the dielectric layer 90 and the cylindrical upper electrode 92 may be formed in a boundary region between the cell region CER and the peripheral circuit region PER. The dielectric layer 90 and the cylindrical upper electrode 92 may be formed on one sidewall of the first peripheral interlayer insulating layer 64 in the boundary region of the cell region CER and the peripheral circuit region PER. The cylindrical upper electrode 92 may be formed as a titanium nitride layer TiN.

The dielectric layer 90 may be formed on one side of the cylindrical lower electrode(s) 66 and on inner walls of the first etching hole(s) 84 and the second etching hole(s) 86. The dielectric layer 90 may be formed on an upper surface or a lower surface of each of the first supporter layer 38, the second supporter layer 44, and the third supporter layer 50.

The cylindrical upper electrode 92 may be formed on the dielectric layer 90 and inside of the first etching hole(s) 84 see FIG. 15 and the second etching hole(s) 86 (see FIG. 15). The cylindrical upper electrode 92 may be disposed on the dielectric layer 90. Accordingly, as shown in FIG. 2, the capacitor structure CAP including the cylindrical lower electrode(s) 66, the dielectric layer 90, and the cylindrical upper electrode 92 may be formed.

In some embodiments, the cylindrical upper electrode 92 may be formed on the dielectric layer 90 but not in the first etching hole(s) 84 of FIG. 15 and the second etching hole(s) 86 of FIG. 15. When a deposition thickness of the cylindrical upper electrode(s) 92 is small, a gap space may be generated in the second etching hole(s) 86 of FIG. 15, and the gap space may be filled with a plate-shaped upper electrode 94 formed later. The dielectric layer 90 and the cylindrical upper electrode 92 may be formed on the first peripheral interlayer insulating layer 64 in the peripheral circuit region PER.

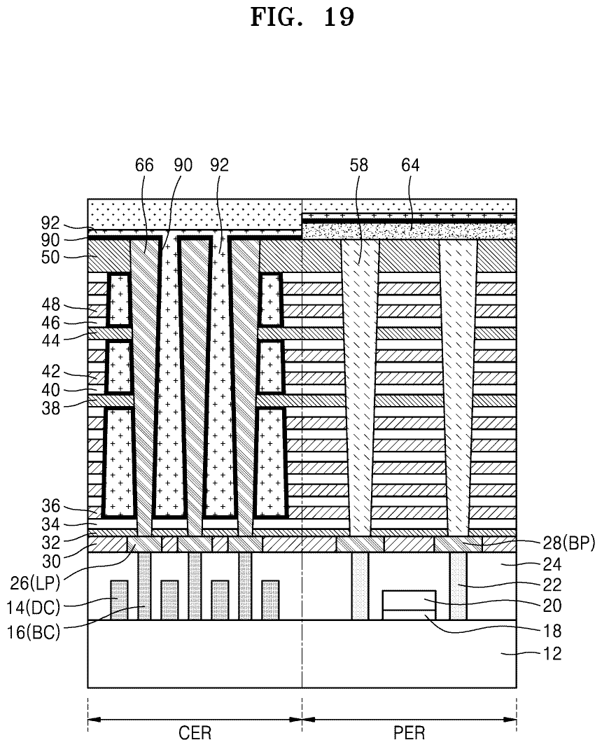

As shown in FIG. 19, a plate-shaped upper electrode material layer 94r may be formed on the cylindrical lower electrode(s) 66, the dielectric layer 90, an upper portion of the cylindrical upper electrode 92 in the cell region CER and the first peripheral interlayer insulating layer 64 in the peripheral circuit region PER. The plate-shaped upper electrode material layer 94r may be formed as an impurity-doped SiGe layer. In some embodiments, when a gap space is generated inside the second etching hole(s) 86 in FIG. 15, the gap space may be filled with the plate-shaped upper electrode material layer 94r.

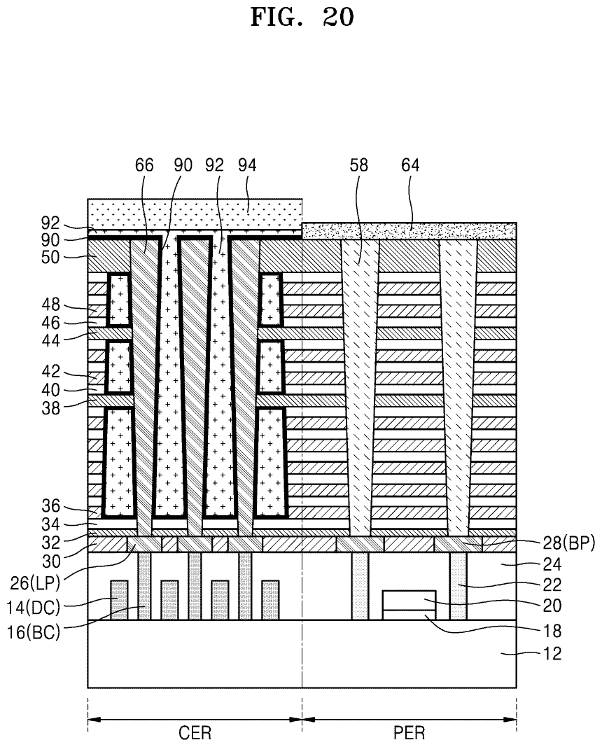

Subsequently, as shown in FIG. 20, the plate-shaped upper electrode 94 may be formed on the cylindrical lower electrode 66, the dielectric layer 90, and the cylindrical upper electrode 92 in the cell region CER by patterning the plate-shaped upper electrode material layer 94r. An upper surface of the plate-shaped upper electrode 94 may be formed to be higher than an upper surface of the first peripheral interlayer insulating layer 64.

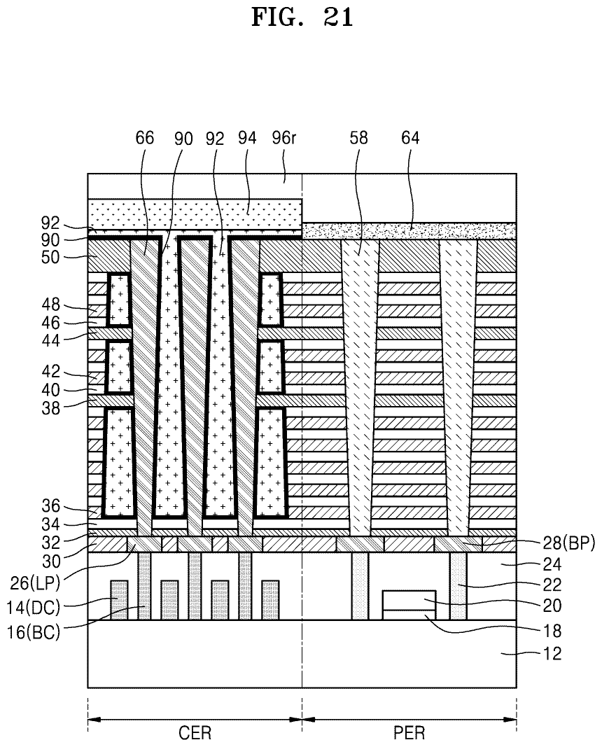

As shown in FIG. 21, a second interlayer insulating material layer 96r may be formed on the plate-shaped upper electrode 94 in the cell region CER and the first peripheral interlayer insulating layer 64 in the peripheral circuit region PER.

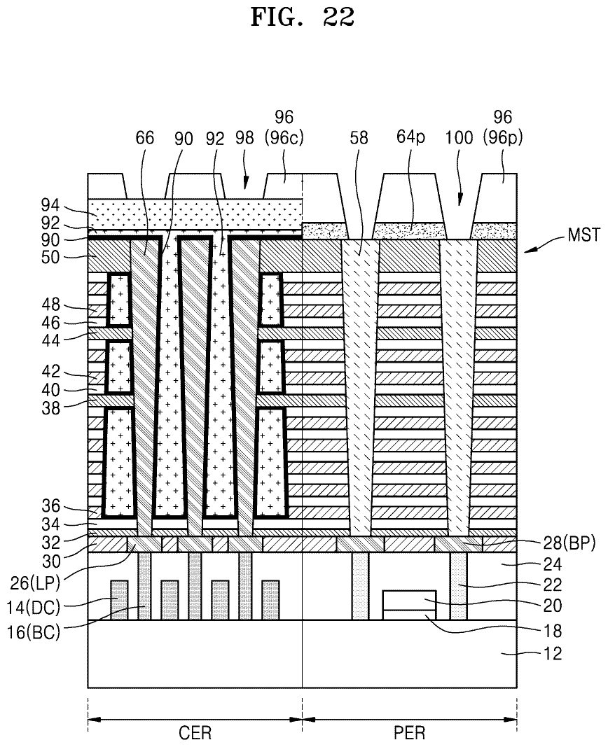

As shown in FIG. 22, at least one first contact hole 98 exposing the plate-shaped upper electrode 94 in the cell region CER and at least one second contact hole 100 exposing the peripheral buried sacrificial layer 58 may be formed by etching the second interlayer insulating material layer 96r and the first peripheral interlayer insulating layer 64 through a photolithography process.

The second interlayer insulating material layer 96r and the first peripheral interlayer insulating layer 64 may be the second interlayer insulating layer 96 and a patterned first peripheral interlayer insulating layer (e.g., the peripheral interlayer insulating layer 64p) formed through the photolithography process, respectively. The second interlayer insulating layer 96 may include a second cell interlayer insulating layer 96c formed in the cell region CER and a second peripheral interlayer insulating layer 96p formed in the peripheral circuit region PER.

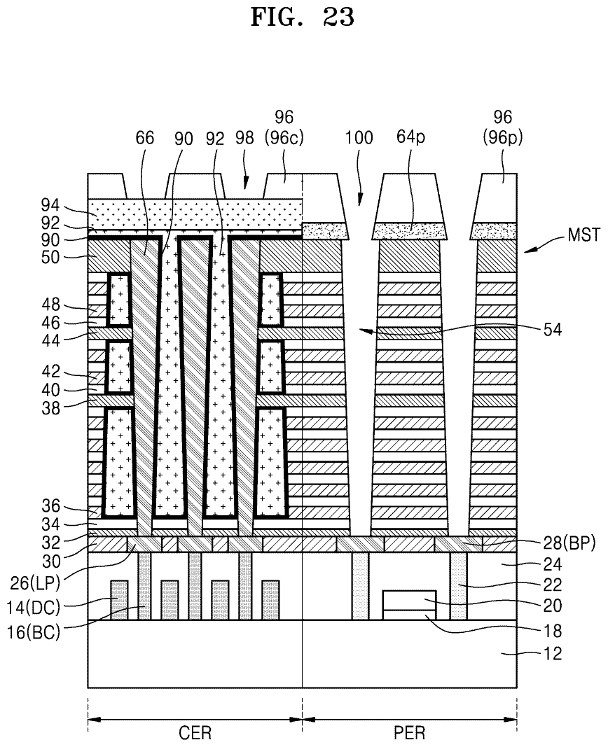

As shown in FIG. 23, the peripheral buried sacrificial layer 58 of FIG. 22 may be removed from the second through hole(s) 54 in the peripheral circuit region PER. Due to such removal, the peripheral conductive pad(s) 28 in the peripheral circuit region PER may be exposed.

Subsequently, as shown in FIG. 2, the cell metal contact layer 106, the first peripheral metal contact layer 104, and the second peripheral metal contact layer 108 may be formed by burying a metal material, such as tungsten, in each of the first contact hole(s) 98 (see FIG. 23) in the cell region CER, and the second through hole(s) 54 (see FIG. 23) and the second contact hole(s) 100 (see FIG. 23) in the peripheral circuit region PER, respectively. The cell metal contact layer 106 may be connected to the plate-shaped upper electrode 94. The first peripheral metal contact layer 104 may be connected to the peripheral conductive pad(s) 28 in the mold structure MST. The second peripheral metal contact layer 108 may be connected to the first peripheral metal contact layer 104. Through such a manufacturing process, the semiconductor device EM1 of FIG. 2 may be completed.

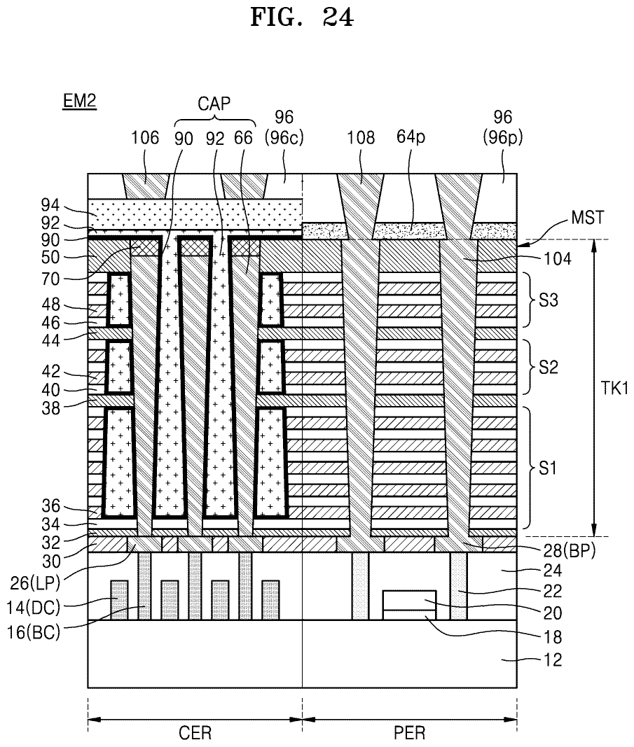

FIG. 24 is a cross-sectional view for explaining a semiconductor device EM2 according to an embodiment.

Specifically, the semiconductor device EM2 may be the same as the semiconductor device EM1 of FIG. 2, except that a protective electrode layer 70 may be further disposed on the cylindrical lower electrode(s) 66. In FIG. 24, the same reference numerals as in FIG. 2 denote the same members. For FIG. 24, descriptions given with reference to FIG. 2 may be briefly described or omitted.

In the semiconductor device EM2, the first contact 14, the second contact 16, and a third contact 22 may be disposed on the substrate 12 having the cell region CER and the peripheral circuit region PER. A peripheral transistor including the peripheral gate insulating layer 18 and the peripheral gate electrode 20 may be disposed in the peripheral circuit region PER.

The cell conductive pad 26 connected to the second contact 16 may be disposed in the cell region CER, and the peripheral conductive pad 28 connected to the third contact 22 in the peripheral circuit region PER may be disposed. The mold structure MST may be disposed on the cell conductive pad 26 and the peripheral conductive pad 28. The configuration of the mold structure MST has been described above, and thus a repeated description thereof may be omitted herein.

The capacitor structure CAP penetrating the mold structure MST and connected to the cell conductive pad 26 may be disposed in the cell region CER. The capacitor structure CAP may include the cylindrical lower electrode(s) 66, the dielectric layer 90, and the cylindrical upper electrode 92. The cylindrical lower electrode(s) 66 may be formed on the cell conductive pad 26.

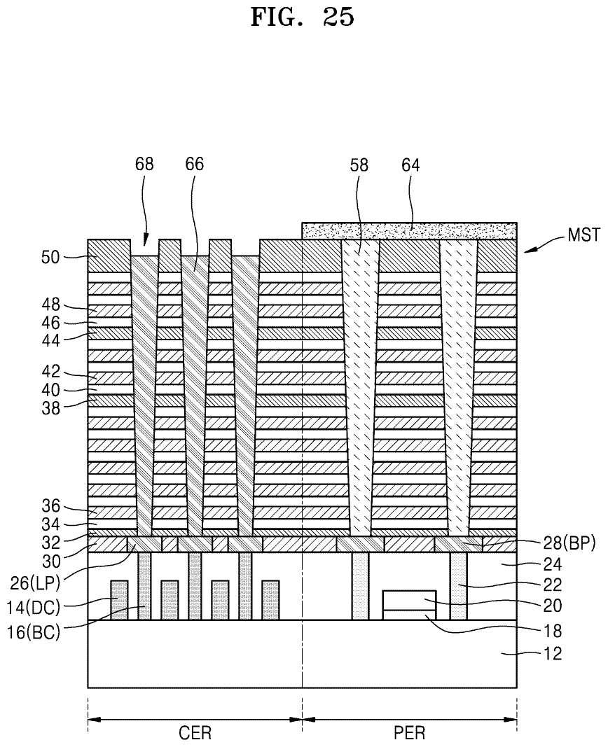

In the semiconductor device EM2, the protective electrode layer 70 may be disposed on the cylindrical lower electrode(s) 66. The protective electrode layer 70 may be buried in the recess hole 68 of FIG. 25 in which the cylindrical lower electrode 66 is recessed as described below. The protective electrode layer 70 may be formed as a metal layer such as, for example, a tungsten layer. A first peripheral metal contact layer 104 penetrating the mold structure MST and connected to the peripheral conductive pad 28 may be disposed in the peripheral circuit region PER.

The capacitor structure CAP including the protective electrode layer 70 and the first peripheral metal contact layer 104 may have the same height TK1. The plate-shaped upper electrode 94 may be disposed on the protective electrode layer 70, the dielectric layer 90, and the cylindrical upper electrode(s) 92 in the cell region CER. The protective electrode layer 70 may be disposed between the cylindrical lower electrode(s) 66 and the dielectric layer 90.

In the peripheral circuit region PER, the first peripheral interlayer insulating layer 64p may be disposed on the third supporter layer 50 of the mold structure MST. The second interlayer insulating layer 96 may be disposed on the plate-shaped upper electrode 94 in the cell region CER and the first peripheral interlayer insulating layer 64p in the peripheral circuit region PER. The second interlayer insulating layer 96 may include a second cell interlayer insulating layer 96c formed in the cell region CER and a second peripheral interlayer insulating layer 96p formed in the peripheral circuit region PER.

The cell region CER may include a cell metal contact layer 106 connected to the plate-shaped upper electrode 94 in the second cell interlayer insulating layer 96c. The peripheral circuit region PER may include the second peripheral metal contact layer 108 connected to the first peripheral metal contact layer 104. The semiconductor device EM2 configured as described above may further include the protective electrode layer 70 to protect the cylindrical lower electrode(s) 66 in a manufacturing process.

FIGS. 25 to 27 are cross-sectional views for explaining a method of manufacturing the semiconductor device EM2 of FIG. 24 according to an embodiment.

Specifically, in FIGS. 25 to 27, the same reference numerals as in FIG. 24 denote the same members. In FIGS. 25 to 27, descriptions given with reference to FIGS. 3 to 23 and 24 may be briefly described or omitted.

The manufacturing process of FIGS. 3 to 12 may be performed. Accordingly, the cylindrical lower electrode(s) 66 buried in the first through hole 52 in the cell region CER may be formed. The cylindrical lower electrode(s) 66 may be connected to the cell conductive pad(s) 26 in the cell region CER.

Referring to FIG. 25, the recess hole(s) 68 may be formed by recessing an upper portion of the cylindrical lower electrode(s) 66. The recess hole 68 may be formed below a surface of the third supporter layer 50. The recess hole 68 may be formed by etching an upper portion of the cylindrical lower electrode 66.

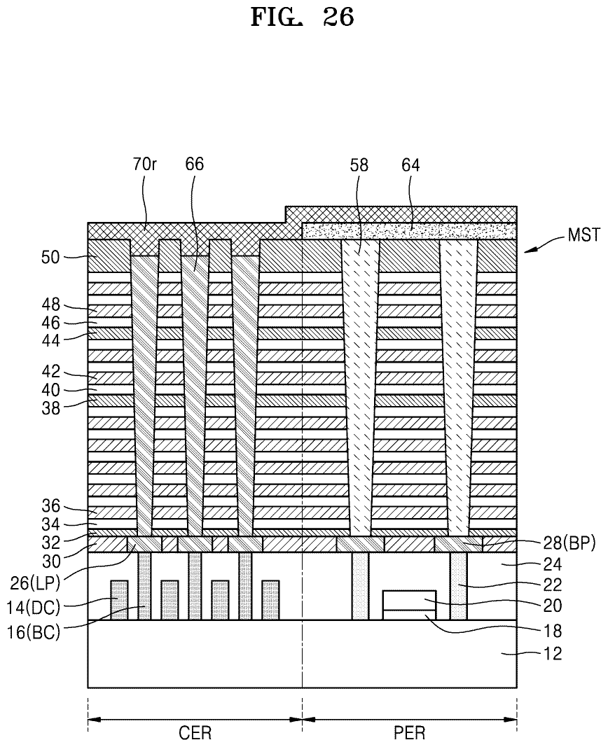

Referring to FIG. 26, a protective electrode material layer 70r is formed on the third supporter layer 50 and the first peripheral interlayer insulating layer 64. The protective electrode material layer 70r may be formed as a metal layer such as, for example, a tungsten layer.

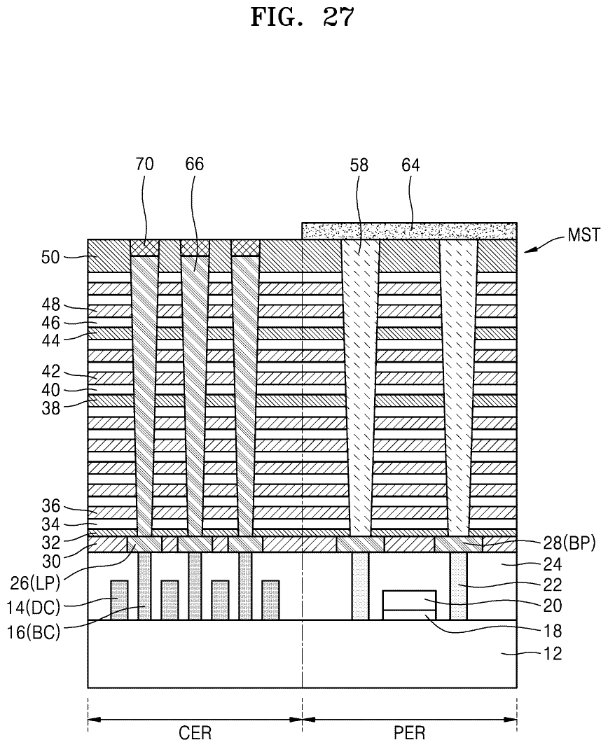

Referring to FIG. 27, the protective electrode layer 70 buried in the recess hole 68 in FIG. 25 may be formed by etching or etching back the protective electrode material layer 70r. The protective electrode layer 70 may be disposed on the cylindrical lower electrode(s) 66.

After the manufacturing process of FIG. 27, the manufacturing process of FIGS. 13 to 23 may be performed. Subsequently, as shown in FIG. 24, a cell metal contact layer 106, a first peripheral metal contact layer 104, and a second peripheral metal contact layer 108 may be formed in the cell region CER and the peripheral circuit region PER. The cell metal contact layer 106 may be connected to the plate-shaped upper electrode 94. The first peripheral metal contact layer 104 may be connected to the peripheral conductive pad 28 in the mold structure MST. The second peripheral metal contact layer 108 may be connected to the first peripheral metal contact layer 104. Through such a manufacturing process, the semiconductor device EM2 of FIG. 24 may be completed.

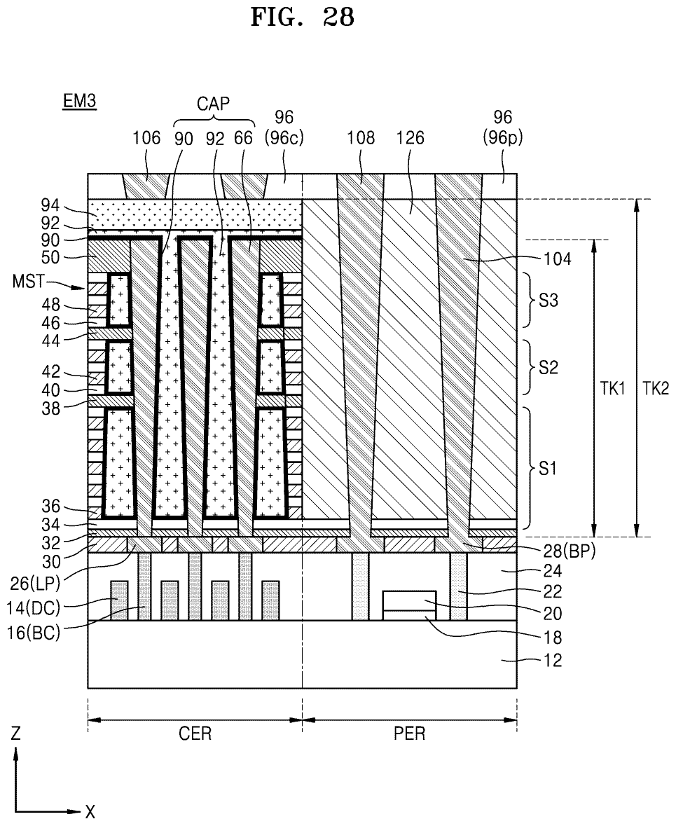

FIG. 28 is a cross-sectional view for explaining a semiconductor device EM3 according to an embodiment.

Specifically, the semiconductor device EM3 may be the same as the semiconductor device EM1 of FIG. 2, except that the first peripheral metal contact layer 104 is formed in a peripheral buried insulating layer 126 in the peripheral circuit region PER. In FIG. 28, the same reference numerals as in FIG. 2 denote the same members. In FIG. 28, descriptions given with reference to FIG. 2 may be briefly described or omitted.

The first contact 14, the second contact 16, and a third contact 22 may be disposed on the substrate 12 having the cell region CER and the peripheral circuit region PER. A peripheral transistor including the peripheral gate insulating layer 18 and the peripheral gate electrode 20 may be disposed in the peripheral circuit region PER.

The cell conductive pad 26 connected to the second contact 16, and the peripheral conductive pad 28 connected to the third contact 22 in the peripheral circuit region PER may be disposed in the cell region CER. The mold structure MST may be disposed on the cell conductive pad 26. The configuration of the mold structure MST has been described above, and thus a repeated description thereof may be omitted herein. In some embodiments, the etching stopper layer 32 and the first sacrificial layer 34 constituting the mold structure MST may be disposed in the peripheral circuit region PER.

The capacitor structure CAP penetrating the mold structure MST and connected to the cell conductive pad 26 may be disposed in the cell region CER. The capacitor structure CAP may include the cylindrical lower electrode(s) 66, the dielectric layer 90, and the cylindrical upper electrode 92. The cylindrical lower electrode 66 may be formed on the cell conductive pad 26. The plate-shaped upper electrode 94 may be disposed on the cylindrical lower electrode(s) 66, the dielectric layer 90, and the cylindrical upper electrode 92 in the cell region CER.

In the semiconductor device EM3, a peripheral buried insulating layer 126 may be disposed on the peripheral conductive pad 28 in the peripheral circuit region PER. When the etching stopper layer 32 and the first sacrificial layer 34 are disposed in the peripheral circuit region PER, the peripheral buried insulating layer 126 may be disposed on the first sacrificial layer 34. The peripheral buried insulating layer 126 may be formed as a silicon oxide layer.

The first peripheral metal contact layer 104 penetrating the peripheral buried insulating layer 126, the etching stopper layer 32, and the first sacrificial layer 34 and connected to the peripheral conductive pad 28 may be disposed in the peripheral circuit region PER. A height TK2 of the first peripheral metal contact layer 104 may be greater than the height TK1 of the capacitor structure CAP.

The second interlayer insulating layer 96 may be disposed on the plate-shaped upper electrode 94 in the cell region CER and the peripheral buried insulating layer 126 in the peripheral circuit region PER. The second interlayer insulating layer 96 may include the second cell interlayer insulating layer 96c formed in the cell region CER and the second peripheral interlayer insulating layer 96p formed in the peripheral circuit region PER.

The cell region CER may include the cell metal contact layer 106 connected to the plate-shaped upper electrode 94 in the second cell interlayer insulating layer 96c. The peripheral circuit region PER may include the second peripheral metal contact layer 108 connected to the first peripheral metal contact layer 104. The first peripheral metal contact layer 104 and the second peripheral metal contact layer 108 may be formed through the same process and may be a single body. The semiconductor device EM3 configured as described above may include the peripheral buried insulating layer 126 in the peripheral circuit region PER to easily form the first peripheral metal contact layer 104 or the second peripheral metal contact layer 108.

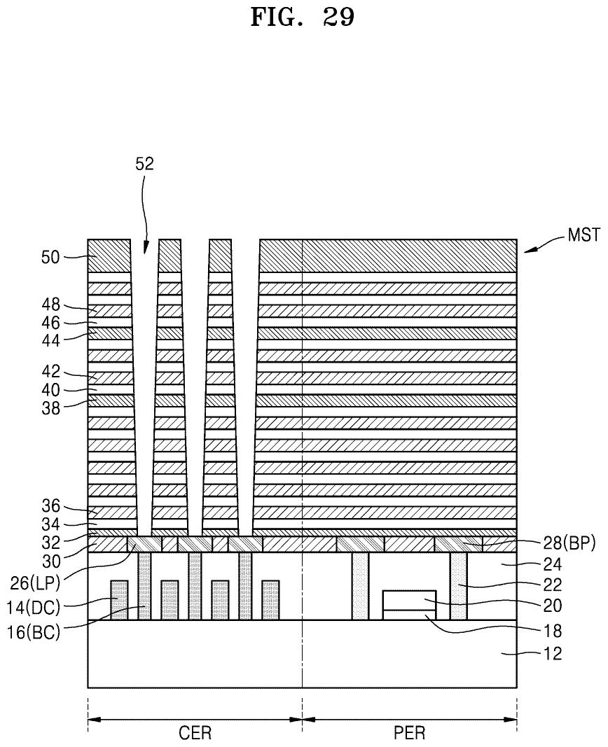

FIGS. 29 to 41 are cross-sectional views for explaining a method of manufacturing the semiconductor device EM3 of FIG. 28 according to an embodiment.

Specifically, in FIGS. 29 to 41, the same reference numerals as in FIG. 28 denote the same members. In FIGS. 29 to 41, descriptions given with reference to FIGS. 3 to 23 and 28 may be briefly described or omitted.

Previously, the manufacturing process of FIG. 3 may be performed. In this case, the mold structure MST may be formed on the cell conductive pad 26, the peripheral conductive pad 28, and the second insulating layer 30 in the cell region CER and the peripheral circuit region PER.

As shown in FIG. 29, the first through hole 52 may be formed on the cell conductive pad 26 by etching the mold structure MST through a photolithography process. The first through hole 52 may expose the cell conductive pad 26.

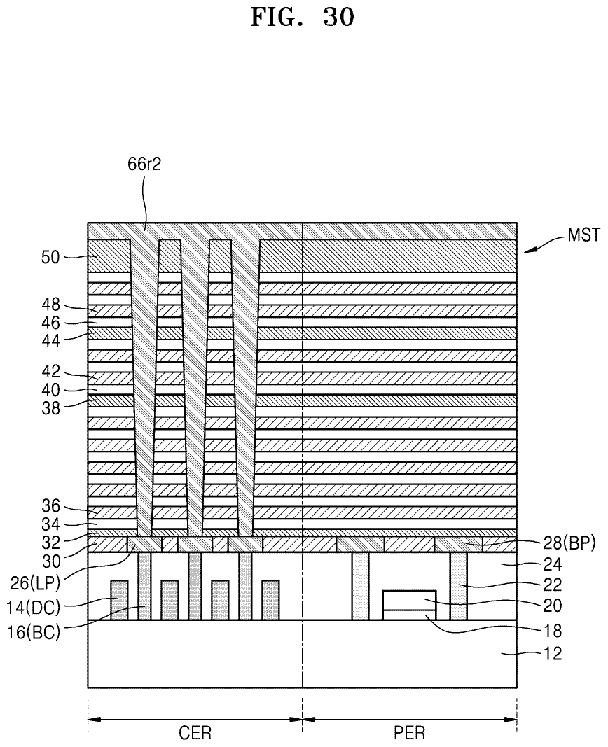

As shown in FIG. 30, a first conductive layer 66r2 may be formed on the mold structure MST in the cell region CER and the peripheral circuit region PER to fill the first through hole 52 in the cell region CER. The first conductive layer 66r2 may include a titanium nitride layer TiN.

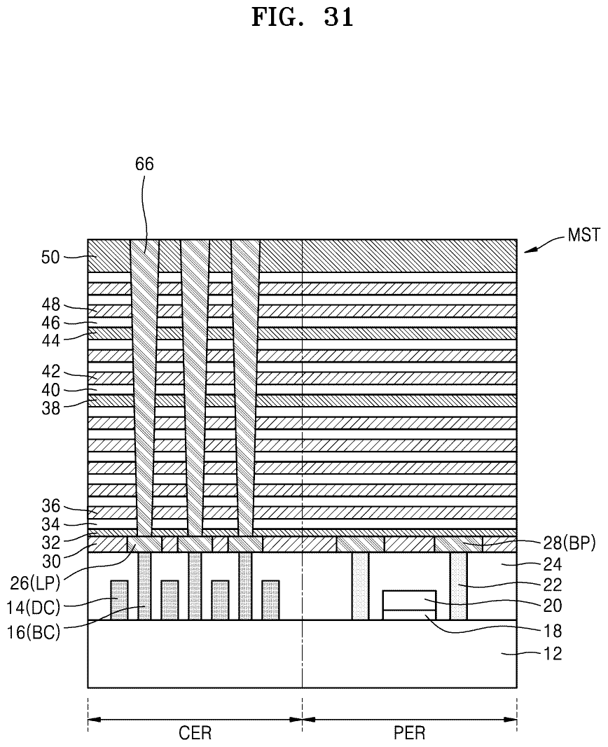

As shown in FIG. 31, the cylindrical lower electrode(s) 66 buried in the first through hole(s) 52 in the cell region CER may be formed by etching back the first conductive layer 66r2. The cylindrical lower electrode(s) 66 may be connected to the cell conductive pad(s) 26 in the cell region CER.

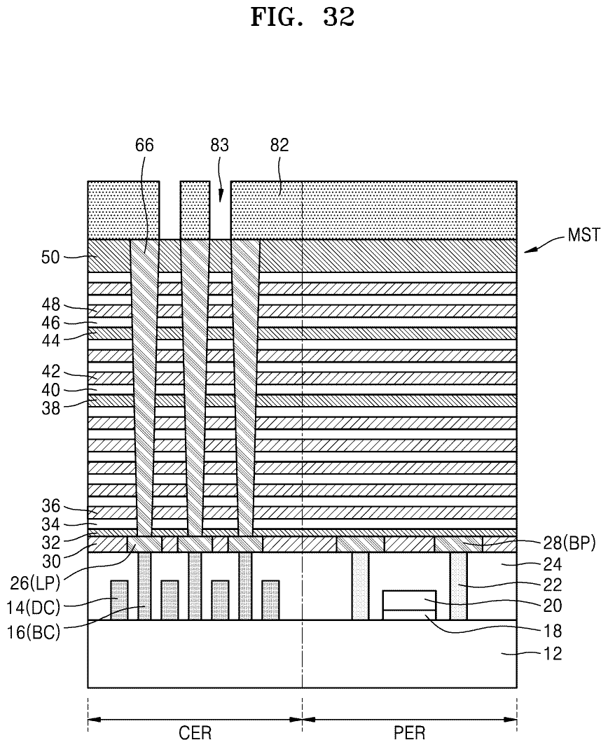

Referring to FIGS. 32 to 34, the first hard mask layer 82 may be formed on the mold structure MST and the cylindrical lower electrode(s) 66. The first hard mask layer 82 may include the mold exposure hole 83 exposing the mold structure MST in the cell region CER.

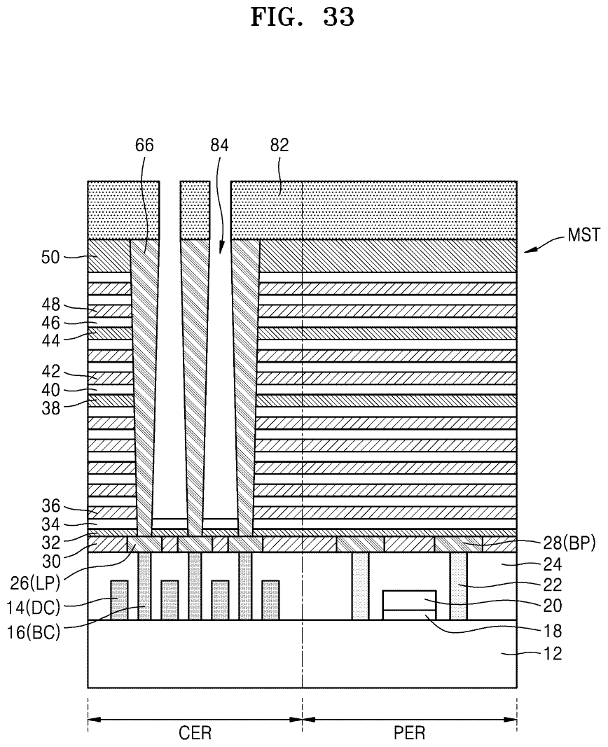

As shown in FIG. 33, the first etching hole 84 may be formed between the cylindrical lower electrodes 66 by etching the mold structure MST in the cell region CER by using the first hard mask layer 82 as an etching mask. The first etching hole 84 may be formed by etching the mold structure MST in the cell region CER exposed by the mold exposure hole 83.

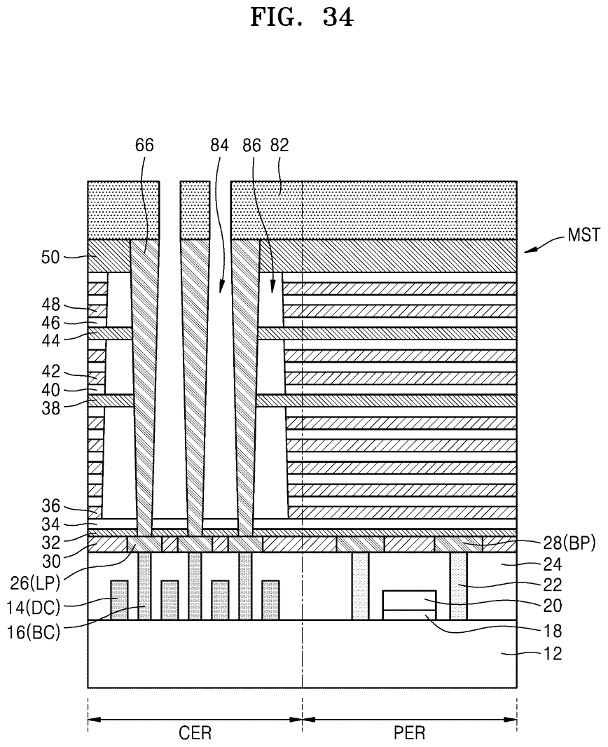

As shown in FIG. 34, the second etching hole 86 may be formed in a lower portion of the first hard mask layer 82. The second etching hole 86 may be formed at one side of the cylindrical lower electrode 66 by additionally etching the mold structure MST in the lower portion of the first hard mask layer 82.

Through the processes of FIGS. 33 and 34, portions of the mold structure MST may be removed between the cylindrical lower electrodes 66, and a part of the mold structure MST may remain in an edge part of the cell region CER and a left edge part of FIG. 15. Formation of the first etching hole 84 and the second etching hole 86 in the cell region CER has been described in detail with reference to FIGS. 16 and 17, and thus a repeated description thereof may be omitted.

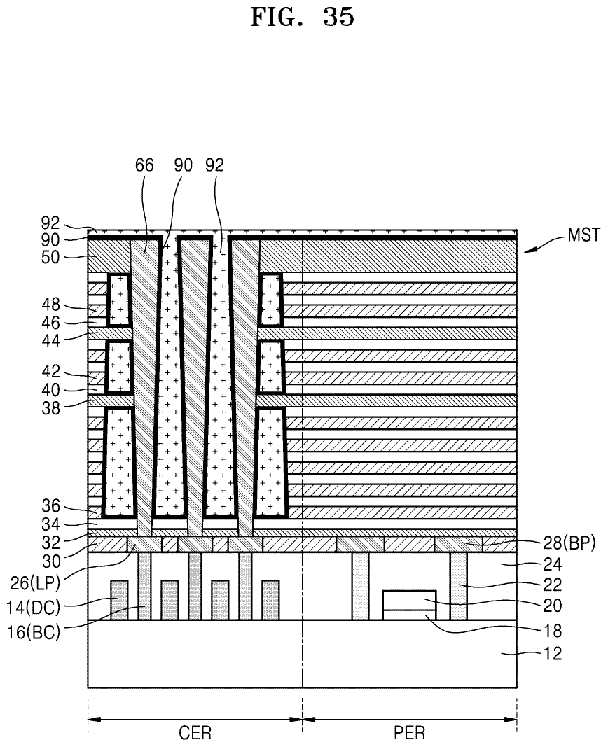

As shown in FIG. 35, after the first hard mask layer 82 is removed, the dielectric layer 90 and the cylindrical upper electrode 92 may be formed on the cylindrical lower electrode(s) 66 inside the first etching hole(s) 84 and the second etching hole(s) 86 in the cell region CER. The cylindrical upper electrode 92 may include a titanium nitride layer TiN.

The dielectric layer 90 may be formed on one side of the cylindrical lower electrode(s) 66 and on inner walls of the first etching hole(s) 84 and the second etching hole(s) 86. In some embodiments, the dielectric layer 90 may also be formed on an upper surface of the cylindrical lower electrode(s) 66.

The dielectric layer 90 may surround the cylindrical lower electrode(s) 66. The dielectric layer 90 may be formed on one side of the cylindrical lower electrode(s) 66. The dielectric layer 90 may be formed on upper surfaces or lower surfaces of the first supporter layer 38, the second supporter layer 44, and the third supporter layer 50. The cylindrical upper electrode 92 may be formed on the dielectric layer 90.

The cylindrical upper electrode 92 may be disposed between the cylindrical lower electrodes 66 on the dielectric layer 90. The cylindrical upper electrode 92 may be formed to fill the inside of the first etching hole 84 and the second etching hole 86 on the dielectric layer 90. Accordingly, as shown in FIG. 28, the capacitor structure CAP including the cylindrical lower electrode(s) 66, the dielectric layer 90, and the cylindrical upper electrode 92 may be formed. The dielectric layer 90 and the cylindrical upper electrode 92 may be formed on the third supporter layer 50 in the peripheral circuit region PER.

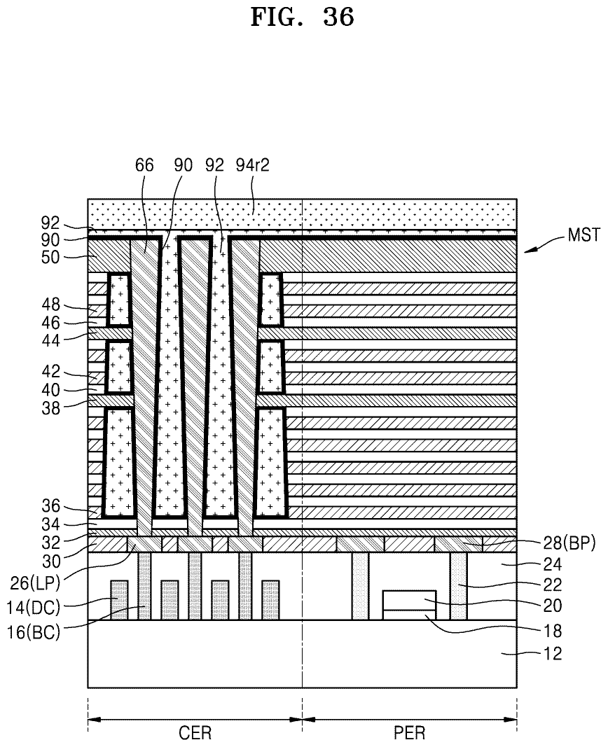

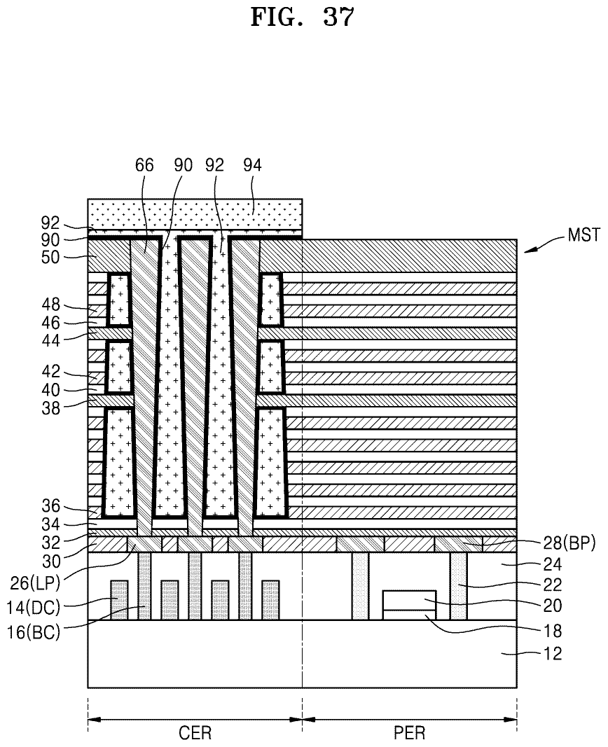

As shown in FIG. 36, a plate-shaped upper electrode material layer 94r2 may be formed on the cylindrical upper electrode 92 in the cell region CER and the peripheral circuit region PER. The plate-shaped upper electrode material layer 94r2 may include an impurity-doped SiGe layer. As shown in FIG. 37, the plate-shaped upper electrode 94 may be formed on the cylindrical upper electrode 92 in the cell region CER by patterning the plate-shaped upper electrode material layer 94r.

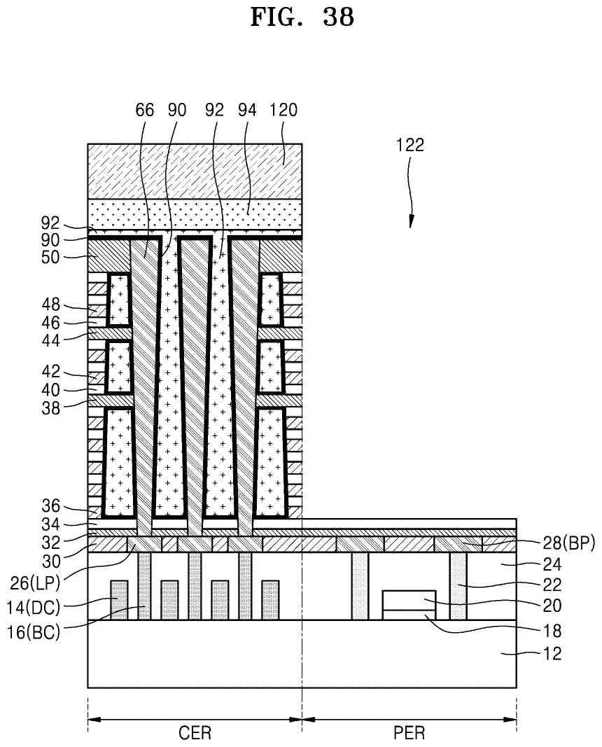

As shown in FIG. 38, a second hard mask layer 120 may be formed on the plate-shaped upper electrode 94. A peripheral hole 122 may be formed by etching the mold structure MST of FIG. 37 in the peripheral circuit region PER by using the second hard mask layer 120 as an etching mask. The second hard mask layer 120 may include a photoresist. When the plate-shaped upper electrode 94 is used as a mask, the second hard mask layer 120 may not be formed.

When the etching stopper layer 32 and the first sacrificial layer 34 on the etching stopper layer 32 are formed in the peripheral circuit region PER, the peripheral hole 122 may be formed on the first sacrificial layer 34.

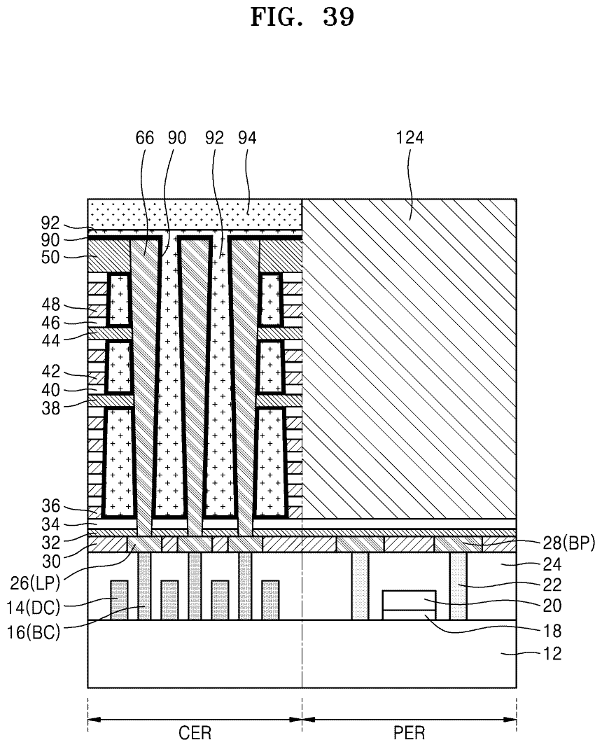

As shown in FIG. 39, a peripheral buried insulating material layer 124 may be formed to fill the peripheral hole 122 in the peripheral circuit region PER. The peripheral buried insulating material layer 124 may be formed by depositing in the peripheral hole 122 to sufficiently fill the peripheral hole 122 and performing a planarization process. The peripheral buried insulating material layer 124 may include a silicon oxide layer.

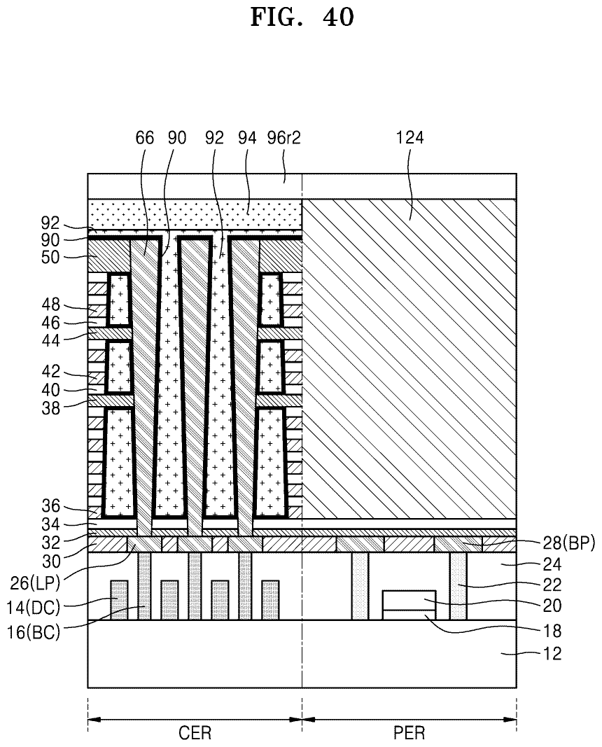

As shown in FIG. 40, a second interlayer insulating material layer 94r2 may be formed on the plate-shaped upper electrode 94 and the peripheral buried insulating material layer 124 in the cell region CER.

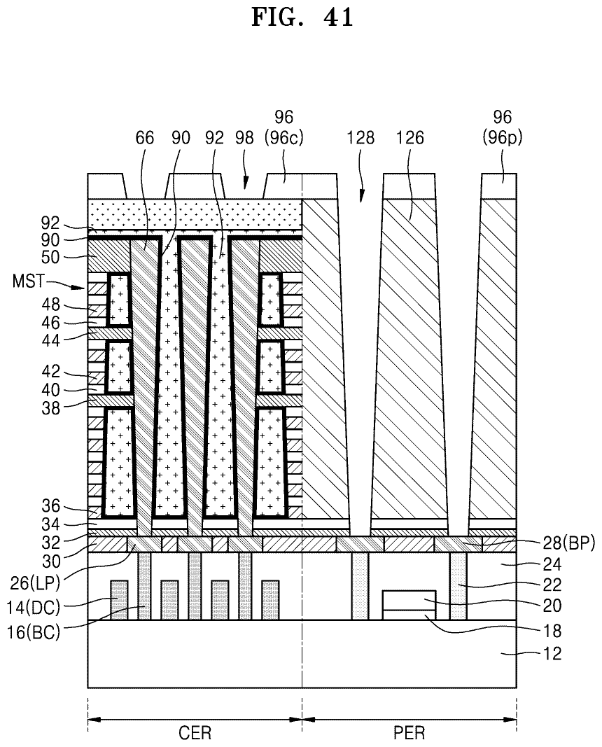

As shown in FIG. 41, a first contact hole 98 exposing the plate-shaped upper electrode 94 in the cell region CER and a second contact hole 128 exposing the peripheral conductive pad 28 may be formed by etching the second interlayer insulating material layer 96r2 of FIG. 40 and the peripheral buried insulating material layer 124 of FIG. 40 through a photolithography process.

The second interlayer insulating material layer 96r2 of FIG. 40 and the peripheral buried insulating material layer 124 of FIG. 40 may become the second interlayer insulating layer 96 and the peripheral buried insulating layer 126, respectively, through the photolithography process. The second interlayer insulating layer 96 may include a second cell interlayer insulating layer 96c formed in the cell region CER and a second peripheral interlayer insulating layer 96p formed in the peripheral circuit region PER.

Subsequently, as shown in FIG. 28, the cell metal contact layer 106, the first peripheral metal contact layer 104, and the second peripheral metal contact layer 108 may be formed by burying a metal material, such as tungsten, in each of the first contact hole 98 of FIG. 41 in the cell region CER and the second contact hole 128 of FIG. 41. The cell metal contact layer 106 may be connected to the plate-shaped upper electrode 94. The first peripheral metal contact layer 104 and the second peripheral metal contact layer 108 may be formed as the same body. The first peripheral metal contact layer 104 may be connected to the peripheral conductive pad 28 in the peripheral buried insulating layer 126. Through such a manufacturing process, the semiconductor device EM3 of FIG. 28 may be completed.

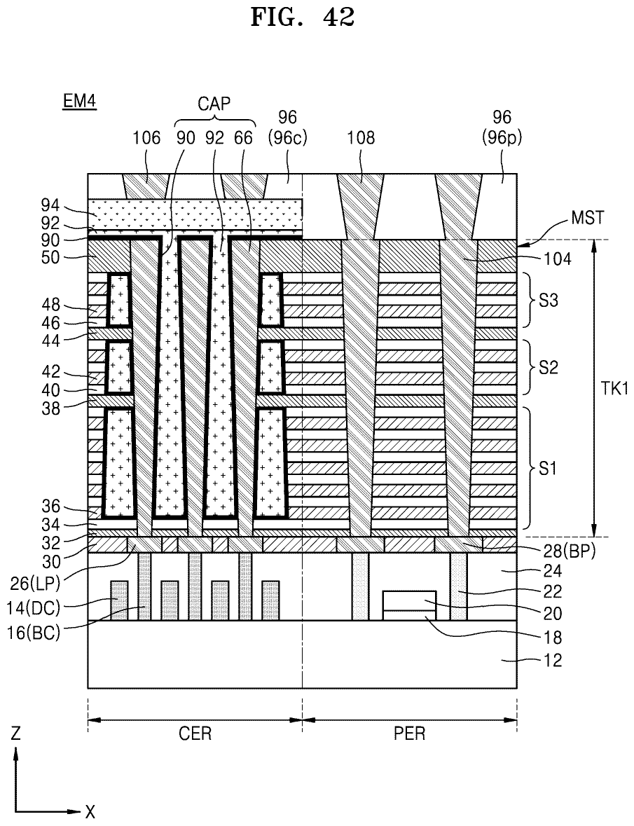

FIG. 42 is a cross-sectional view for explaining a semiconductor device EM4 according to an embodiment.

Specifically, the semiconductor device EM4 may be the same as the semiconductor device EM1 of FIG. 2 except that the first peripheral interlayer insulating layer 64p may not be disposed on the third supporter layer 50 in the peripheral circuit region PER. In FIG. 42, the same reference numerals as in FIG. 2 denote the same members. In FIG. 24, descriptions given with reference to FIG. 2 may be briefly described or omitted.

In the semiconductor device EM4, the mold structure MST may be disposed on the cell conductive pad 26 and the peripheral conductive pad 28. The configuration of the mold structure MST has been described above, and thus a repeated description thereof may be omitted herein.

The capacitor structure CAP penetrating the mold structure MST and connected to the cell conductive pad 26 may be disposed in the cell region CER. The capacitor structure CAP may include the cylindrical lower electrode(s) 66, the dielectric layer 90, and the cylindrical upper electrode 92. The cylindrical lower electrode(s) 66 may be formed on the cell conductive pad(s) 26.

The plate-shaped upper electrode 94 may be disposed on the dielectric layer 90 and the cylindrical upper electrode 92 in the cell region CER. Unlike FIG. 2, in the peripheral circuit region PER, the first peripheral interlayer insulating layer 64p may not be disposed on the third supporter layer 50 constituting the mold structure MST. The second interlayer insulating layer 96 may be disposed on the plate-shaped upper electrode 94 in the cell region CER and the third supporter layer 50 in the peripheral circuit region PER. The second interlayer insulating layer 96 may include the second cell interlayer insulating layer 96c formed in the cell region CER and the second peripheral interlayer insulating layer 96p formed in the peripheral circuit region PER.

The cell region CER may include the cell metal contact layer 106 connected to the plate-shaped upper electrode 94 in the second cell interlayer insulating layer 96c. The peripheral circuit region PER may include the second peripheral metal contact layer 108 connected to the first peripheral metal contact layer 104. Unlike FIG. 2, in the semiconductor device EM4 configured as described above, the first peripheral interlayer insulating layer 64p may not be disposed on the third supporter layer 50 in the peripheral circuit region PER. Accordingly, the semiconductor device EM4 may be easily manufactured by simplifying the manufacturing process.

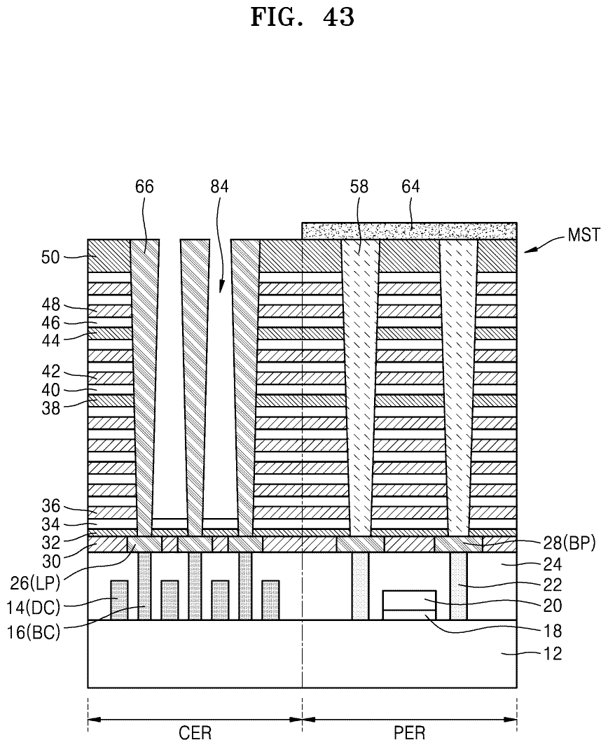

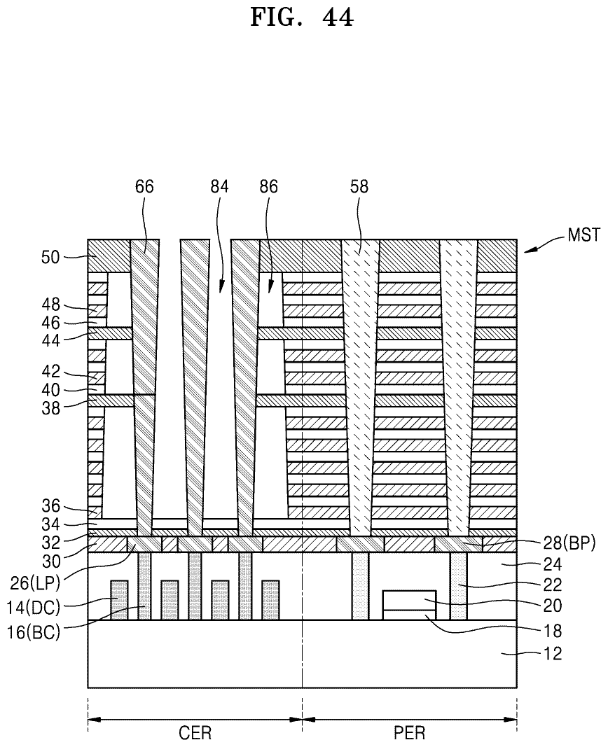

FIGS. 43 and 44 are cross-sectional views for explaining a method of manufacturing a semiconductor device of FIG. 42 according to an embodiment.

Specifically, in FIGS. 43 to 44, the same reference numerals as in FIG. 42 denote the same members. In FIGS. 43 to 44, descriptions given with reference to FIGS. 3 to 23 may be briefly described or omitted.

After performing the manufacturing process of FIGS. 3 to 14, the first hard mask layer 82 may be removed. Thereafter, a resultant product of FIG. 43 may be prepared.

Referring to FIG. 43, the first etching hole(s) 84 may be formed between the cylindrical lower electrodes 66 of the mold structure MST in the cell region CER. The first etching hole 84 may be formed by etching the mold structure MST in the cell region CER. The first peripheral interlayer insulating layer 64 may remain on the third supporter layer 50 and the peripheral buried sacrificial layer 58 in the peripheral circuit region PER.

Referring to FIG. 44, the first peripheral interlayer insulating layer 64 may be removed simultaneously with the formation of the second etching hole(s) 86. The second etching hole(s) 86 may be formed at one side of the cylindrical lower electrode(s) 66 by additionally etching the mold structure MST in lower portions of first to fourth supporter layers in the cell region CER, and the first peripheral interlayer insulating layer 64 may be etched and removed. The second etching hole(s) 86 may be formed in a lower portion of the third supporter layer 50, a lower portion of the second supporter layer 44, and a lower portion of the first supporter layer 38.

After the manufacturing process of FIG. 44, the manufacturing process of FIGS. 18 to 23 may be performed. By removing the first peripheral interlayer insulating layer 64, the manufacturing process of FIGS. 18 to 23 may be easily performed.

Subsequently, as shown in FIG. 42, the cell metal contact layer 106, the first peripheral metal contact layer 104, and the second peripheral metal contact layer 108 may be formed in the cell region CER and the peripheral circuit region PER. The cell metal contact layer 106 may be connected to the plate-shaped upper electrode 94.

The first peripheral metal contact layer 104 may be connected to the peripheral conductive pad 28 in the mold structure MST. The second peripheral metal contact layer 108 may be connected to the first peripheral metal contact layer 104. Through such a manufacturing process, the semiconductor device EM4 of FIG. 42 may be completed.

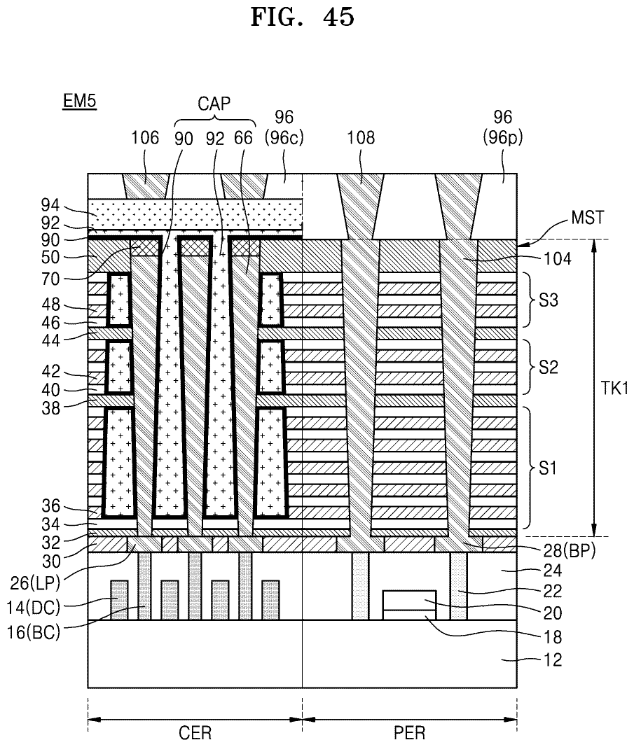

FIG. 45 is a cross-sectional view for explaining a semiconductor device EM5 according to an embodiment.

Specifically, the semiconductor device EM5 may be the same as the semiconductor device EM2 of FIG. 24, except that the first peripheral interlayer insulating layer 64p may not be disposed on the third supporter layer 50 in the peripheral circuit region PER. In FIG. 45, the same reference numerals as in FIG. 24 denote the same members. In FIG. 45, descriptions given with reference to FIG. 24 may be briefly described or omitted.

In the semiconductor device EM5, the mold structure MST may be disposed on the cell conductive pad 26 and the peripheral conductive pad 28. The configuration of the mold structure MST has been described above, and thus a repeated description thereof may be omitted herein.

The capacitor structure CAP penetrating the mold structure MST and connected to the cell conductive pad 26 may be disposed in the cell region CER. The capacitor structure CAP may include the cylindrical lower electrode(s) 66, the dielectric layer 90, and the cylindrical upper electrode 92. The cylindrical lower electrode(s) 66 may be formed on the cell conductive pad(s) 26. The protective electrode layer 70 may be formed on the cylindrical lower electrode(s) 66.

The plate-shaped upper electrode 94 may be disposed on the dielectric layer 90 and the cylindrical upper electrode 92 in the cell region CER. Unlike FIG. 24, in the peripheral circuit region PER, the first peripheral interlayer insulating layer 64p may not be disposed on the third supporter layer 50 of the mold structure MST. The second interlayer insulating layer 96 may be disposed on the plate-shaped upper electrode 94 in the cell region CER and the third supporter layer 50 in the peripheral circuit region PER. The second interlayer insulating layer 96 may include the second cell interlayer insulating layer 96c formed in the cell region CER and the second peripheral interlayer insulating layer 96p formed in the peripheral circuit region PER.

The cell region CER may include the cell metal contact layer 106 connected to the plate-shaped upper electrode 94 in the second cell interlayer insulating layer 96c. The peripheral circuit region PER may include the second peripheral metal contact layer 108 connected to the first peripheral metal contact layer 104.

Unlike FIG. 24, in the semiconductor device EM5 configured as described above, the first peripheral interlayer insulating layer 64p may not be disposed on the third supporter layer 50 in the peripheral circuit region PER. Accordingly, the semiconductor device EM5 may be easily manufactured by simplifying the manufacturing process.

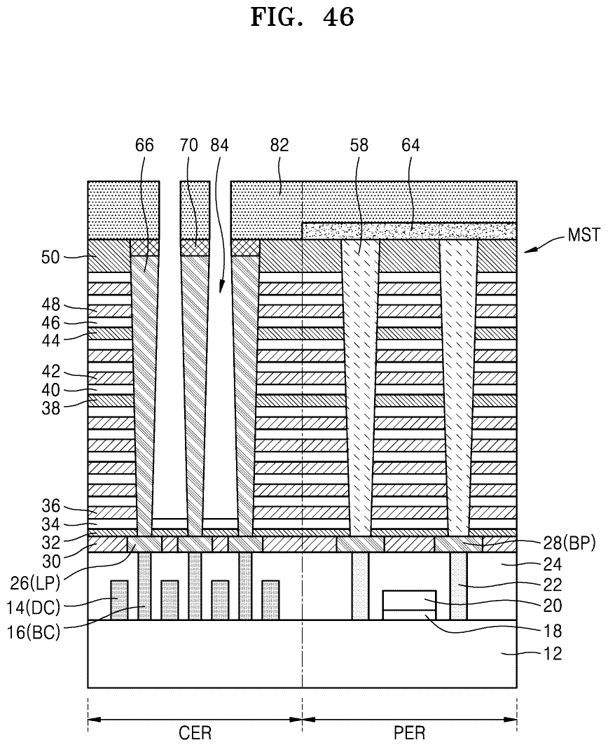

FIGS. 46 to 48 are cross-sectional views for explaining a method of manufacturing the semiconductor device EM5 of FIG. 45 according to an embodiment.

Specifically, in FIGS. 46 to 48, the same reference numerals as in FIG. 45 denote the same members. In FIGS. 46 to 48, descriptions given with reference to FIGS. 3 to 27 may be briefly described or omitted.

The manufacturing processes of FIGS. 3 to 12, 25 to 27, and 13 and 14 described above are sequentially performed first. Thereafter, a resultant product of FIG. 46 may be prepared.

Referring to FIG. 46, the first etching hole(s) 84 may be formed between the cylindrical lower electrode(s) 66 in the cell region CER and through the protective electrode layer 70 on the cylindrical lower electrodes 66. The first etching hole(s) 84 may be formed by etching the mold structure MST in the cell region CER exposed by the mold exposure hole 83.

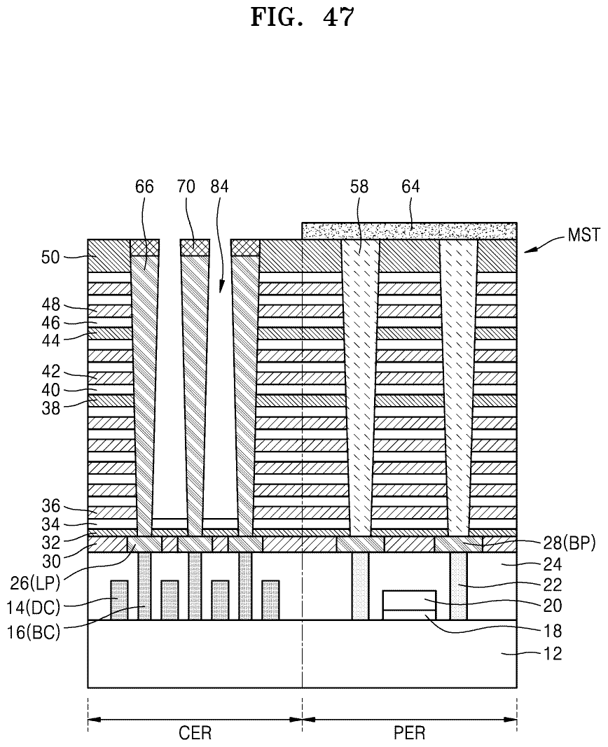

Referring to FIG. 47, the first hard mask layer 82 may be removed. The first etching hole(s) 84 may be formed between the cylindrical lower electrodes 66 of the mold structure MST in the cell region CER. The first etching hole 84 may be formed by etching the mold structure MST in the cell region CER. The first peripheral interlayer insulating layer 64 may remain on the third supporter layer 50 and the peripheral buried sacrificial layer 58 in the peripheral circuit region PER.

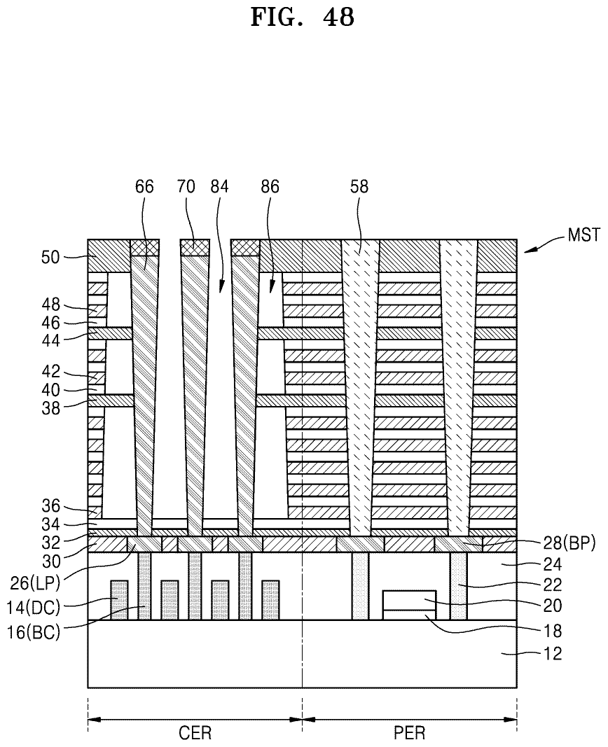

Referring to FIG. 48, the first peripheral interlayer insulating layer 64 may be removed simultaneously with the formation of the second etching hole(s) 86. The second etching hole(s) 86 may be formed at one side of the cylindrical lower electrode(s) 66 by additionally etching the mold structure MST in lower portions of first to fourth supporter layers in the cell region CER, and the first peripheral interlayer insulating layer 64 may be etched and removed. The second etching hole(s) 86 may be formed in a lower portion of the third supporter layer 50, a lower portion of the second supporter layer 44, and a lower portion of the first supporter layer 38.

After the manufacturing process of FIG. 48, the manufacturing process of FIGS. 18 to 23 may be performed. By removing the first peripheral interlayer insulating layer 64, the manufacturing process of FIGS. 18 to 23 may be easily performed.

Subsequently, as shown in FIG. 45, the cell metal contact layer 106, the first peripheral metal contact layer 104, and the second peripheral metal contact layer 108 may be formed in the cell region CER and the peripheral circuit region PER. The cell metal contact layer 106 may be connected to the plate-shaped upper electrode 94.

The first peripheral metal contact layer 104 may be connected to the peripheral conductive pad 28 in the mold structure MST. The second peripheral metal contact layer 108 may be connected to the first peripheral metal contact layer 104. Through such a manufacturing process, the semiconductor device EM5 of FIG. 45 is completed.

While non-limiting example embodiments of the present disclosure have been particularly described herein with reference to the accompanying drawings, it will be understood that various changes in form and details may be made therein without departing from the spirit and scope of the present disclosure.

What is claimed is:

1. A semiconductor device comprising:
a substrate comprising a cell region;
a cell conductive pad in the cell region;
a mold structure on the cell conductive pad, wherein the mold structure comprises:
an etching stopper layer on the cell conductive pad;
a first stack that comprises a plurality of first sacrificial layers and a plurality of second sacrificial layers that are alternately stacked on the etching stopper layer;
a first supporter layer on the first stack;
a second stack comprising a plurality of third sacrificial layers and a plurality of fourth sacrificial layers that are alternately stacked on the first supporter layer;
a second supporter layer on the second stack;
a third stack comprising a plurality of fifth sacrificial layers and a plurality of sixth sacrificial layers that are alternately stacked on the second supporter layer; and
a third supporter layer on the third stack;
a capacitor structure penetrating the mold structure in the cell region, wherein the capacitor structure comprises:
a cylindrical lower electrode;
a dielectric layer on one side wall of the cylindrical lower electrode; and
a cylindrical upper electrode on one side wall of the dielectric layer; and
a plate-shaped upper electrode on the cylindrical lower electrode, the dielectric layer, and the cylindrical upper electrode in the cell region.

2. The semiconductor device of claim 1, further comprising a cell metal contact layer on the plate-shaped upper electrode.

3. The semiconductor device of claim 1, wherein the plurality of first sacrificial layers, the plurality of third sacrificial layers, and the plurality of fifth sacrificial layers comprise a same material as each other,
wherein the plurality of second sacrificial layers, the plurality of fourth sacrificial layers, and the plurality of sixth sacrificial layers comprise a same material as each other, and
wherein the plurality of first sacrificial layers, the plurality of third sacrificial layers, and the plurality of fifth sacrificial layers comprise materials having etching speeds different from etching speeds of materials of the plurality of second sacrificial layers, the plurality of fourth sacrificial layers, and the plurality of sixth sacrificial layers.

4. The semiconductor device of claim 1, wherein the etching stopper layer, the first supporter layer, the second supporter layer, and the third supporter layer comprise materials having etching speeds lower than etching speeds of materials of the plurality of first sacrificial layers, the plurality of second sacrificial layers, the plurality of third sacrificial layers, the plurality of fourth sacrificial layers, the plurality of fifth sacrificial layers, and the plurality of sixth sacrificial layers.

5. The semiconductor device of claim 1, wherein
each of the plurality of first sacrificial layers, the plurality of third sacrificial layers, and the plurality of fifth sacrificial layers comprise a silicon oxide layer,
each of the plurality of second sacrificial layers, the plurality of fourth sacrificial layers, and the plurality of sixth sacrificial layers comprise a silicon nitride layer, and
each of the etching stopper layer, the first supporter layer, the second supporter layer, and the third supporter layer comprise SiBN, SiOCN, or SiCN.

6. The semiconductor device of claim 5, wherein the silicon nitride layer of the plurality of second sacrificial layers has a nitrogen concentration different from a nitrogen concentration of the silicon nitride layer of each of the plurality of fourth sacrificial layers and the plurality of sixth sacrificial layers.

7. The semiconductor device of claim 1, wherein the plurality of first sacrificial layers, the plurality of third sacrificial layers, and the plurality of fifth sacrificial layers have thicknesses different from thicknesses of the plurality of second sacrificial layers, the plurality of fourth sacrificial layers, and the plurality of sixth sacrificial layers.

8. The semiconductor device of claim 1, wherein the first stack, the second stack, and the third stack have different thicknesses from each other.

9. The semiconductor device of claim 1, wherein the etching stopper layer, the first supporter layer, the second supporter layer, and the third supporter layer have thicknesses different from thicknesses of the plurality of first sacrificial layers, the plurality of second sacrificial layers, the plurality of third sacrificial layers, the plurality of fourth sacrificial layers, the plurality of fifth sacrificial layers, and the plurality of sixth sacrificial layers.

10. A semiconductor device comprising:
a substrate comprising a cell region and a peripheral circuit region;
a cell conductive pad in the cell region;
a peripheral conductive pad in the peripheral circuit region;
a mold structure on the cell conductive pad and the peripheral conductive pad, wherein the mold structure comprises:
an etching stopper layer on the cell conductive pad and the peripheral conductive pad;
a first stack comprising a plurality of first sacrificial layers and a plurality of second sacrificial layers that are alternately stacked on the etching stopper layer;
a first supporter layer on the first stack;
a second stack comprising a plurality of third sacrificial layers and a plurality of fourth sacrificial layers that are alternately stacked on the first supporter layer;
a second supporter layer on the second stack;
a third stack comprising a plurality of fifth sacrificial layers and a plurality of sixth sacrificial layers that are alternately stacked on the second supporter layer; and
a third supporter layer on the third stack;
a capacitor structure penetrating the mold structure in the cell region, wherein the capacitor structure comprises a cylindrical lower electrode, a dielectric layer on one side wall of the cylindrical lower electrode, and a cylindrical upper electrode on one side wall of the dielectric layer;
a first peripheral metal contact layer penetrating the mold structure in the peripheral circuit region; and
a plate-shaped upper electrode on the cylindrical lower electrode, the dielectric layer, and the cylindrical upper electrode in the cell region.

11. The semiconductor device of claim 10, wherein a height of the capacitor structure in the cell region is the same as a height of a metal contact layer in the peripheral circuit region.

12. The semiconductor device of claim 10, wherein a lower surface of the plate-shaped upper electrode has a height that is the same as a height of a lower surface of a metal contact layer in the peripheral circuit region.

13. The semiconductor device of claim 10, further comprising:
a cell metal contact layer on the plate-shaped upper electrode; and
a second peripheral metal contact layer on the mold structure and connected to the first peripheral metal contact layer in the peripheral circuit region.

14. The semiconductor device of claim 10, further comprising a protective electrode layer between the cylindrical lower electrode and the plate-shaped upper electrode.

15. The semiconductor device of claim 10, wherein
the plurality of first sacrificial layers, the plurality of third sacrificial layers, and the plurality of fifth sacrificial layers comprise a same material as each other,
the plurality of second sacrificial layers, the plurality of fourth sacrificial layers, and the plurality of sixth sacrificial layers comprise a same material as each other, and
the plurality of first sacrificial layers, the plurality of third sacrificial layers, and the plurality of fifth sacrificial layers comprise materials having etching speeds different from etching speeds of materials of the plurality of second sacrificial layers, the plurality of fourth sacrificial layers, and the plurality of sixth sacrificial layers.

16. The semiconductor device of claim 10, wherein the etching stopper layer, the first supporter layer, the second supporter layer, and the third supporter layer comprise materials having etching speeds lower than etching speeds of materials of the plurality of first sacrificial layers, the plurality of second sacrificial layers, the plurality of third sacrificial layers, the plurality of fourth sacrificial layers, the plurality of fifth sacrificial layers, and the plurality of sixth sacrificial layers.

17. A semiconductor device comprising:
a substrate comprising a cell region and a peripheral circuit region;
a cell conductive pad in the cell region;
a peripheral conductive pad in the peripheral circuit region;
a mold structure on the cell conductive pad, wherein the mold structure comprises:
an etching stopper layer on the cell conductive pad;
a first stack comprising a plurality of first sacrificial layers and a plurality of second sacrificial layers that are alternately stacked on the etching stopper layer;
a first supporter layer on the first stack;
a second stack comprising a plurality of third sacrificial layers and a plurality of fourth sacrificial layers that are alternately stacked on the first supporter layer;
a second supporter layer on the second stack;
a third stack comprising a plurality of fifth sacrificial layers and a plurality of sixth sacrificial layers that are alternately stacked on the second supporter layer; and
a third supporter layer on the third stack;
a capacitor structure penetrating the mold structure in the cell region, wherein the capacitor structure comprises:
a cylindrical lower electrode;
a dielectric layer on one side wall of the cylindrical lower electrode; and
a cylindrical upper electrode on one side wall of the dielectric layer;
a peripheral buried insulating layer in the peripheral circuit region;
a metal contact layer penetrating the peripheral buried insulating layer in the peripheral circuit region; and
a plate-shaped upper electrode on the cylindrical lower electrode, the dielectric layer, and the cylindrical upper electrode in the cell region.

18. The semiconductor device of claim 17, wherein a height of the metal contact layer in the peripheral circuit region is greater than a height of the capacitor structure in the cell region.

19. The semiconductor device of claim 17, further comprising:
a cell metal contact layer on the plate-shaped upper electrode;
a first peripheral metal contact layer penetrating the mold structure in the peripheral circuit region; and
a second peripheral metal contact layer on the peripheral buried insulating layer and connected to the first peripheral metal contact layer in the peripheral circuit region.

20. The semiconductor device of claim 17, wherein
the plurality of first sacrificial layers, the plurality of third sacrificial layers, and the plurality of fifth sacrificial layers comprise a same material as each other,
the plurality of second sacrificial layers, the plurality of fourth sacrificial layers, and the plurality of sixth sacrificial layers comprise a same material as each other,
the plurality of first sacrificial layers, the plurality of third sacrificial layers, and the plurality of fifth sacrificial layers comprise materials having etching speeds different from etching speeds of materials of the plurality of second sacrificial layers, the plurality of fourth sacrificial layers, and the plurality of sixth sacrificial layers, and
the etching stopper layer, the first supporter layer, the second supporter layer, and the third supporter layer comprise materials having etching speeds lower than the etching speeds of the materials of the plurality of first sacrificial layers, the plurality of second sacrificial layers, the plurality of third sacrificial layers, the plurality of fourth sacrificial layers, the plurality of fifth sacrificial layers, and the plurality of sixth sacrificial layers.
